(19) United States
(12) Patent Application Publication
(10) Pub. No.: US 2024/0176240 A1
(43) Pub. Date: May 30, 2024

(54) PHOTOSENSITIVE RESIN COMPOSITION, PRODUCTION METHOD FOR POLYIMIDE CURED FILM USING SAME, AND POLYIMIDE CURED FILM

(71) Applicant: ASAHI KASEI KABUSHIKI KAISHA, Tokyo (JP)

(72) Inventors: Satoshi SHIBUI, Tokyo (JP); Suzuka MATSUMOTO, Tokyo (JP)

(73) Assignee: ASAHI KASEI KABUSHIKI KAISHA, Tokyo (JP)

(21) Appl. No.: 18/273,123

(22) PCT Filed: Jan. 12, 2022
(86) PCT No.: PCT/JP2022/000792

§ 371 Date: Jul. 19, 2023

(30) Foreign Application Priority Data
Jan. 22, 2021 (JP) 2021-008731

(51) Int. Cl. G03F 7/038; C08G 73/12; C08J 5/18

(52) U.S. Cl. CPC G03F 7/038; C08G 73/121; C08J 5/18; C08J 2379/08

(57) ABSTRACT

Provided is photosensitive resin composition that has low dielectric characteristics, low water vapor permeability, and good chemical resistance and can form a cured relief pattern at high resolution. This photosensitive resin composition includes 100 parts by mass of a polyimide precursor resin, 0.5-10 parts by mass of a photopolymerization initiator, and 50-500 parts by mass of a solvent. The polyimide precursor resin includes at least one terminal structure selected from the group consisting of general formulas (1)-(3). The total value for the aliphatic hydrocarbon group concentration T of the polyimide precursor resin is 4-35 wt %.

### TECHNICAL FIELD

The present disclosure relates to a photosensitive resin composition, and a method for producing a polyimide cured film and a polyimide cured film using the same.

### BACKGROUND ART

There have conventionally been used, as insulating materials for electronic components, passivation films, surface protective films and interlayer insulating films for semiconductor devices, polyimide resins, polybenzoxazole resins and phenolic resins which have excellent heat resistance, electrical properties and mechanical properties. Of these, those provided in the form of a photosensitive resin composition can easily form a heat-resistant film by application, exposure, development and ring closure treatment (imidation, benzoxazolization) and thermal crosslinking due to curing of the composition. Such photosensitive resin composition has characteristics of enabling significant reduction in the process compared to conventional non-photosensitive materials, and is therefore used in the fabrication of semiconductor devices.

Incidentally, semiconductor devices (hereinafter also referred to as “elements”) are mounted on printed circuit boards in various manners depending on the purposes. A conventional element was generally fabricated by a wire bonding method in which a fine wire is used to connect an external terminal (pad) of the element to a lead frame. However, today, the speed of devices has increased and the operating frequency has reached up to GHz, a difference in wiring length of each terminal in mounting have come to affect the operation of devices. Therefore, mounting of elements for high-end applications requires precise control of the mounting wiring length, and thus wire bonding is no longer sufficient to meet these requirements.

Therefore, there has been proposed flip-chip mounting in which a rewiring layer is formed on the surface of a semiconductor chip and, after forming bumps (electrodes) thereon, the chip is flipped over and the chip is directly mounted on a printed circuit board. Since this flip-chip mounting can accurately control the wiring distance, it has been adopted for high-end devices which handle high-speed signals, or mobile phones due to its small mounting size, and demand is growing rapidly. More recently, there has been proposed a semiconductor chip mounting technique called fan-out wafer level package (FOWLP) in which a pre-processed wafer is diced to produce individual chips and the individual chips are reconstructed on a support, and after sealing with a mold resin, a rewiring layer is formed after stripping the support (for example,

PTL 1). In the fan-out wafer level package, since the rewiring layer is formed at a small thickness, the height of the package can be reduced, and there are advantages such as high-speed transmission and cost reduction.

In recent years, significant increase in volume of information communication has necessitated a shift to 5th generation (5G) communication using a frequency of 3 GHz or more, or to ultra-high frequency bands from quasi-millimeter wave bands (20 GHz to 30 GHz) to millimeter wave bands (30 GHz or more) where a wider frequency bandwidth can be easily secured, thus requiring high-frequency compatibility not only in the printed circuit boards but also in the semiconductor chips on which the boards are mounted. To reduce transmission loss, there has been developed an antenna-in-package (AiP) in which a front-end module (FEM) which transmits and receives radio waves, and an antenna are integrated (see, for example, PTL 2 below). The short wiring length of the AiP makes it possible to suppress the transmission loss which increases in proportion to the wiring length.

In general, transmission loss increases as the frequency of an electrical signal increases. To reduce the transmission loss in a high frequency band, there are roughly two methods, a method of reducing dielectric loss and a method of reducing conductor loss. As for the former, the photosensitive resin composition is required to have low dielectric properties (low dielectric loss tangent, low dielectric constant) (for example, PTL 3). For the latter, there is a need to reduce the roughness of the metal rewiring layer.

As an interlayer material for protecting the rewiring layer, not only low dielectric properties but also high adhesion between the rewiring metal layer and the resin layer, and chemical resistance are required from the viewpoint of the reliability. Therefore, especially in recent years, it is required that the temperature for heat-curing the rewiring layer be lower. As such a photosensitive resin composition, for example, PTL 4 is cited.

### CITATION LIST

### Patent Literature

[PTL 1] JP 2005-167191 A

[PTL 2] US 2016/0,104,940 A

[PTL 3] WO 2019/044874 A

[PTL 4] JP 2018-200470 A

### SUMMARY

### Technical Problem

In recent years, due to the diversification of package mounting technology, the types of supports have diversified and the number of rewiring layers has increased, and thus the dielectric constant and dielectric tangent (tan δ) of the insulating material used for wiring formation have a significant impact. When the dielectric constant and dielectric loss tangent are high, the transmission loss increases due to an increase in dielectric loss. While a polyimide resin has high material reliability due to its excellent insulation performance and thermo-mechanical properties, high dielectric constant and dielectric loss tangent are problematic due to the polar functional groups derived from an imide group, the addition of polar functional groups for photosensitization, and additives. The dependence of the dielectric loss tangent on frequency may be sometimes problematic, and it is considered to be preferable that the insulating layer have low moisture permeability.

An object of the present disclosure is to provide a photosensitive resin composition which has low dielectric properties, low moisture permeability and satisfactory chemical resistance, and is capable of forming a cured relief pattern with high resolution, and a method for producing a polyimide cured film and a polyimide cured film using the same.

### Solution to Problem

Examples of the embodiment of the present disclosure are listed in items [1] to below.

[1]

A photosensitive resin composition comprising:
(A) 100 parts by mass of a polyimide precursor resin;
(B) 0.5 to 10 parts by mass of a photopolymerization initiator; and
(C) 50 to 500 parts by mass of a solvent;
wherein the polyimide precursor resin (A) comprises at least one terminal structure selected from the group consisting of the following general formulas (1) to (3):

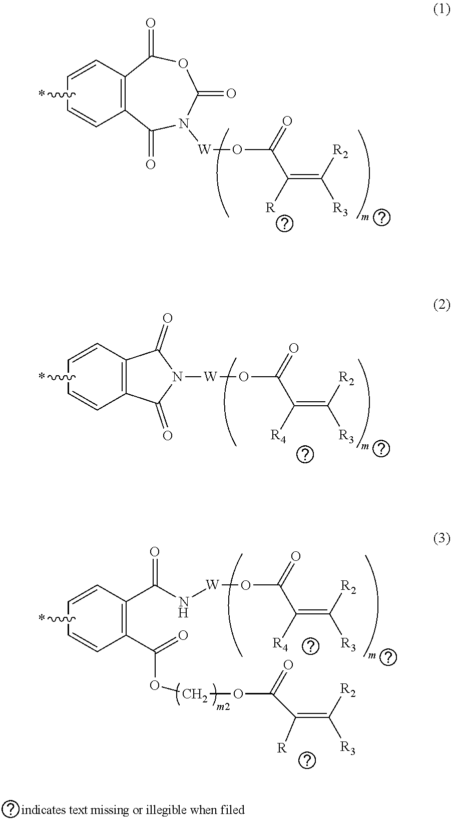

wherein W is a divalent to trivalent organic group, R₁ to R₃ are each independently a hydrogen atom or a monovalent organic group having 1 to 3 carbon atoms, mi is a group represented by an integer of 1 to 2, m₂ is a group represented by an integer of 2 to 10, and * means bonding to the main chain of the resin, and
wherein, in polyimide of a polyimide cured film obtained by heating and curing the photosensitive resin composition at 350° C., aliphatic hydrocarbon group concentration T, which is the ratio of the total molecular weight of aliphatic hydrocarbon groups to the molecular weight of repeating units including structures derived from tetracarboxylic dianhydride and a diamine compound, is 4 wt % to 35 wt %.
   [2]

A photosensitive resin composition comprising:
(A) 100 parts by mass of a polyimide precursor resin;
(B) 0.5 to 10 parts by mass of a photosensitive agent; and
(C) 100 to 300 parts by mass of a solvent;
wherein, in polyimide of a polyimide cured film obtained by heating and curing the photosensitive resin composition at 350° C., aliphatic hydrocarbon group concentration T which is the ratio of the total molecular weight of aliphatic hydrocarbon groups to the molecular weight of repeating units including structures derived from tetracarboxylic dianhydride and a diamine compound, and photosensitive group concentration S which is the ratio of the total molecular weight of photosensitive groups to the molecular weight of repeating units in the polyimide precursor resin (A) satisfy the following formula (1):

−77≤4T−3S≤44 (1)
and wherein the polyimide precursor resin (A) has the other reactive unsaturated bonds which are polymerized by heat or light at the resin end, and are different from the reactive unsaturated bond side chain included in the repeating units.
   [3 ]

The photosensitive resin composition according to item 1 or 2, wherein the polyimide precursor resin (A) is represented by the following general formula (4):

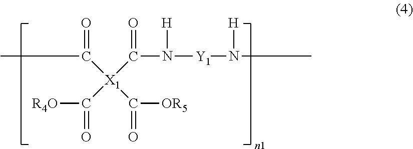

wherein X₁ is a tetravalent organic group having 6 to 40 carbon atoms, Y₁ is a divalent organic group having 6 to 40 carbon atoms, n₁ is an integer of 2 to 150, and R₄ and R₅ are each independently a hydrogen atom or a monovalent organic group having 1 to 40 carbon atoms, in which at least one of R₄ and R₅ is a group represented by the following general formula (5):

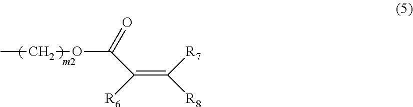

wherein R₆, R₇ and R₈ are each independently a hydrogen atom or a monovalent organic group having 1 to 3 carbon atoms, and m₂ is an integer of 2 to 10.
   [4]

The photosensitive resin composition according to any one of items 1 to 3, wherein photosensitive group concentration S, which is the ratio of the total molecular weight of photosensitive groups to the molecular weight of repeating units in the polyimide precursor resin (A) represented by the general formula (4), is 15 wt % to 35 wt %.

[5 ]

The photosensitive resin composition according to any one of items 1 to 4, wherein the polyimide precursor resin (A) includes a structure represented by the following general formula (6):

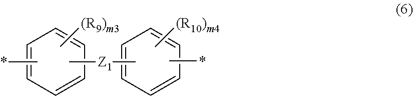

wherein R₉ and R₁₀ are each independently an organic group having 1 to 10 carbon atoms, m₃ and m₄ are an integer selected from 1 to 4, Z is selected from the group consisting of a single bond, an organic group having 1 to 30 carbon atoms and an organic group containing a heteroatom, and * means bonding to the main chain of the resin.
   [6]

The photosensitive resin composition according to any one of items 1 to 5, further comprising (D) a silane coupling agent.

[7]

The photosensitive resin composition according to any one of items 1 to 6, further comprising (E) a radically polymerizable compound.

[8]

The photosensitive resin composition according to any one of items 1 to 7, further comprising (F) a thermal crosslinking agent.

[9]

The photosensitive resin composition according to any one of items 1 to 8, further comprising (G) a filler.

[10]

The photosensitive resin composition according to any one of items 1 to 9, wherein the polyimide precursor resin (A) includes a terminal structure derived from tetracarboxylic dianhydride at the end of the main chain, and
wherein, in ¹H-NMR, when a peak area of an amide group derived from the main chain structure is 1.0, an end-capping value, which indicates an end-capping ratio, is 0.02 or more.
   [11]

A photosensitive resin composition comprising:
(A) 100 parts by mass of a polyimide precursor resin;
(B) 0.5 to 10 parts by mass of a photopolymerization initiator; and
(C) 50 to 500 parts by mass of a solvent;
wherein the polyimide precursor resin (A) includes a terminal structure derived from tetracarboxylic dianhydride at the end of the main chain, and
wherein, in ¹H-NMR, when a peak area of an amide group derived from the main chain structure is 1.0, an end-capping value, which indicates an end-capping ratio, is 0.02 or more.
   [12]

A photosensitive resin composition comprising:
(A) 100 parts by mass of a polyimide precursor resin;
(B) 0.5 to 10 parts by mass of a photopolymerization initiator; and
(C) 50 to 500 parts by mass of a solvent;
wherein the polyimide precursor resin (A) includes a terminal structure derived from diamine at the end of the main chain, and
wherein, in ¹H-NMR, when a peak area of an amide group derived from the main chain structure is 1.0, an end-capping value, which indicates an end-capping ratio, is 0.06 or more.
   [13]

A method for producing a polyimide cured film, the method comprising the following steps:
a step of applying the photosensitive resin composition according to any one of items 1 to 12 on a substrate to form a photosensitive resin layer on the substrate;
a step of heating and drying the obtained photosensitive resin layer;
a step of exposing the heat-dried photosensitive resin layer;
a step of developing the exposed photosensitive resin layer; and
a step of heat-treating the developed photosensitive resin layer to form a polyimide cured film.
   [14]

A method for producing a polyimide cured film, which comprises applying the resin composition according to any one of items 1 to 12 on a substrate, and subjecting the substrate to an exposure treatment, a development treatment and then a heat treatment, wherein the cured film is an insulating film used for rewiring applications, and the cured film has a dielectric loss tangent within a range of 3.0×10⁻³ to 1.3×10⁻² as measured at 40 GHz by the perturbation type split cylinder resonator method.

[15]

A polyimide cured film which has a dielectric loss tangent of 3.0×10⁻³ to 1.3×10⁻² as measured at a frequency of 40 GHz by the perturbation type split cylinder resonator method, and satisfies the following formula (2):

3.0<tan δ₄₀×WVTR<10.0 (2)
wherein tan δ₄₀ represents the dielectric loss tangent as measured at a frequency of 40 GHz by the perturbation type split cylinder resonator method, and WVTR represents the moisture permeability of a 10 μm thick polyimide cured film.
   [16]

The polyimide cured film according to item 15, wherein the dielectric loss tangent as measured at a frequency of 40 GHz by the perturbation type split cylinder resonator method is 3.0×10⁻³ to 1.3×10⁻² and satisfies the following formula (3):

4.0<tan δ₄₀×WVTR×DR<29.0 (3)
wherein tan δ₄₀ represents the dielectric loss tangent as measured at a frequency of 40 GHz by the perturbation type split cylinder resonator method, WVTR represents the moisture permeability of a polyimide cured film in terms of a thickness of 10 μm, and DR represents a dissolution rate in a chemical resistance test.
   [17]

A method for producing a photosensitive resin composition, the photosensitive resin composition comprising:
(A) 100 parts by mass of a polyimide precursor resin;
(B) 0.5 to 10 parts by mass of a photopolymerization initiator; and
(C) 50 to 500 parts by mass of a solvent;
wherein the method comprises a step of synthesizing the polyimide precursor resin (A) and a step of mixing the polyimide precursor resin (A), the photopolymerization initiator (B) and the solvent (C) to obtain a photosensitive resin composition, wherein
the synthesis step comprises the following steps:
a monomer preparation step of obtaining an acid component monomer and/or a diamine monomer having a second compound introducing portion by (i) and/or (ii):
(i) reacting tetracarboxylic dianhydride with a first compound having a reactive substituent which reacts with heat or light to generate a first compound introducing portion and carboxyl groups, reacting with a second compound having a reactive substituent that reacts with heat or light, which is different from the first compound, or reacting tetracarboxylic dianhydride with a second compound having a reactive substituent which reacts with heat or light to generate a second compound introducing portion and carboxyl groups, and then reacting with a first compound having a reactive substituent which reacts with heat or light, which is different from the second compound, to obtain an acid component monomer having a second compound introducing portion, and/or
(ii) reacting a diamine compound with a second compound having a reactive substituent which reacts with heat or light to obtain a diamine monomer having a second compound introducing portion; and
a polymerization step of synthesizing a polyimide precursor by subjecting an acid component monomer and/or a diamine monomer having a second compound introducing portion, tetracarboxylic dianhydride and a diamine compound to a condensation reaction, and
wherein the polyimide precursor resin (A) has a reactive substituent derived from the second compound at the main chain end.
   [18]

A method for producing a polyimide precursor resin, the method comprising the following steps:
a monomer preparation step of obtaining an acid component monomer and/or a diamine monomer having a second compound introducing portion by (i) and/or (ii):
(i) reacting tetracarboxylic dianhydride with a first compound having a reactive substituent which reacts with heat or light to generate a first compound introducing portion and carboxyl groups, reacting with a second compound having a reactive substituent which reacts with heat or light, which is different from the first compound, or reacting tetracarboxylic dianhydride with a second compound having a reactive substituent which reacts with heat or light to generate a second compound introducing portion and carboxyl groups, and then reacting with a first compound having a reactive substituent which reacts with heat or light, which is different from the second compound, to obtain an acid component monomer having a second compound introducing portion, and/or
(ii) reacting a diamine compound with a second compound having a reactive substituent which reacts with heat or light to obtain a diamine monomer having a second compound introducing portion; and
a polymerization step of synthesizing a polyimide precursor by subjecting an acid component monomer and/or a diamine monomer having a second compound introducing portion, tetracarboxylic dianhydride and a diamine compound to a condensation reaction,
wherein the polyimide precursor resin has a reactive substituent derived from the second compound at the main chain end.

### Advantageous Effects of Invention

By using the photosensitive resin composition of the present disclosure, it is possible to produce a cured resin film having excellent relief pattern resolution, low dielectric properties, low moisture permeability and satisfactory chemical resistance. By using a polyimide precursor having specific terminal crosslinking groups and aliphatic hydrocarbon groups, the solubility of the prebaked film in a developing solution is improved, resulting in improvement in the resolution of a relief pattern. An improvement in hydrophobicity and crosslink density in the cured film leads to lower moisture permeability and improved chemical resistance, as well as lower dielectric loss tangent due to an increase in exclusion volume.

### BRIEF DESCRIPTION OF DRAWINGS

FIG. 1 is an example of an NMR spectrum of polyimide obtained by heat-curing a polyimide precursor at 230° C.

FIG. 2 is an example of an NMR spectrum of polyimide obtained by heat-curing a polyimide precursor at 230° C.

### DESCRIPTION OF EMBODIMENTS

Hereinafter, embodiments of the present disclosure will be described in detail.

Throughout the description, structures represented by the same reference numerals in general formulas may be independently selected and may be the same or different from each other, unless otherwise specified, when a plurality of structures are present in the molecule. Structures represented by common symbols in different general formulas are also independently selected and may be the same or different from each other, unless otherwise specified.

### Photosensitive Resin Composition

The photosensitive resin composition of the present disclosure comprises (A) 100 parts by mass of a polyimide precursor resin having a specific terminal structure, (B) 0.5 to 10 parts by mass of a photopolymerization initiator, and (C) 50 to 500 parts by mass of a solvent. The photosensitive resin composition of the present disclosure optionally includes, in addition to the above components, (D) a silane coupling agent, (E) an ethylenically unsaturated group-containing compound, (F) a thermal crosslinking agent, (G) a filler, and other components.

### (A) Polyimide Precursor

### Condition 1

The polyimide precursor resin preferably satisfies at least two conditions (1-i) and (1-ii) below.
(1-i) The polyimide precursor resin includes at least one terminal structure selected from the group consisting of general formulas (1) to (3) below.

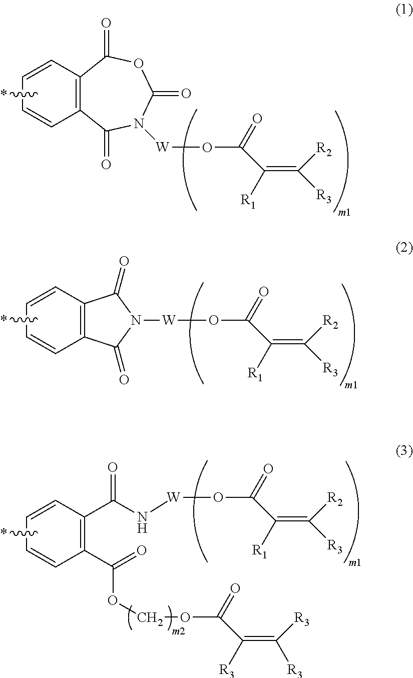

wherein W is a divalent to trivalent organic group, R₁ to R₃ are each independently a hydrogen atom or a monovalent organic group having 1 to 3 carbon atoms, mi is an integer of 1 to 2, m₂ is an integer of 2 to 10, and * means bonding to the main chain of the polyimide precursor resin.
(1-ii) In polyimide of a polyimide cured film obtained by heating and curing the photosensitive resin composition at 350° C., aliphatic hydrocarbon group concentration T, which is the ratio of the total molecular weight of aliphatic hydrocarbon groups to the molecular weight of repeating units including structures derived from tetracarboxylic dianhydride and a diamine compound, is 4 wt % to 35 wt %. When the polyimide precursor satisfies these conditions (1-i) and (1-ii), it is possible to obtain a high-resolution negative photosensitive resin composition which has low dielectric properties, low moisture permeability and satisfactory chemical resistance.

### Method 1 for Introducing Terminal Structure

To form the terminal structures of the general formulas (1) and (2), tetracarboxylic dianhydride having a desired tetravalent organic group X is reacted with a compound having an isocyanate group, followed by reacting with alcohols having a photopolymerizable group (e.g., unsaturated double bond) to prepare a partially imidized or imide-derivatized (structure derived from the general formula (2))/esterified tetracarboxylic acid (hereinafter also referred to as acid/ester/imide body). To promote the reaction between the tetracarboxylic dianhydride and the compound having an isocyanate group, it is possible to use pyridine, triethylamine, dimethylaminopyridine, 1,4-diazabicyclo[2.2.2]octane and the like. Saturated aliphatic alcohols may optionally be used in combination with the alcohols having a photopolymerizable group.

### Method 2 for Introducing Terminal Structure

To form the terminal structure of the general formula (3), tetracarboxylic dianhydride having a desired tetravalent organic group X is reacted with alcohols having a photopolymerizable group (e.g., unsaturated double bond) to prepare a partially esterified tetracarboxylic acid (hereinafter also referred to as acid/ester body), followed by reacting with a compound having an isocyanate group to prepare a partially esterified/amidated tetracarboxylic acid (hereinafter also referred to as acid/ester/amide body). To promote the reaction between the tetracarboxylic dianhydride and the compound having an isocyanate group, it is possible to use pyridine, triethylamine, dimethylaminopyridine, 1,4-diazabicyclo[2.2.2]octane and the like. Saturated aliphatic alcohols may optionally be used in combination with the alcohols having a photopolymerizable group.

The structure of W is not particularly limited, but is preferably a divalent to trivalent organic group having a weight-average molecular weight of less than 300, more preferably a divalent to trivalent organic group having 1 to 5 carbon atoms, and still more preferably a divalent to trivalent organic group having 1 to 3 carbon atoms.

In the reactive terminal structure derived from the tetracarboxylic dianhydride, the polymerization conditions are excessively acidic, and the polymerization system of the resin does not become basic. Therefore, it is preferable from the viewpoint of the dielectric loss tangent because it is difficult to form ends which cause deterioration of the dielectric loss tangent. When the connection structure of the reactive terminal structure is an imide bond or an amide bond represented by the general formulas (1) to (3), the heat resistance and hydrolysis resistance are improved compared to the ester bond or the like, and since the polymerizable functional group does not leave the terminal structure of the resin during the heat treatment process or a reliability test performed under high temperature and high humidity conditions, it is preferable from the viewpoint of the chemical resistance. Further, the terminal polymerizable functional group has a (meth)acrylate group, leading to high reactivity during curing, which is more preferable from the viewpoint of chemical resistance.

“Aliphatic hydrocarbon group concentration T” means the ratio of the total molecular weight of aliphatic hydrocarbon groups to the molecular weight of repeating units including structures derived from tetracarboxylic dianhydride and a diamine compound in polyimide of a polyimide cured film obtained by heating and curing the photosensitive resin composition at 350° C. The condition of heating and curing at 350° C. is intended to clarify the criteria for aliphatic hydrocarbon group concentration T by using, as the standard, the state where the polyimide precursor is almost 100% imidized, and it is not intended that the photosensitive resin composition is heated and cured at 350° C. in actual use. Here, “aliphatic hydrocarbon group” is a hydrocarbon group having at least one structure selected from the group consisting of a saturated aliphatic chain, an unsaturated aliphatic chain and an alicyclic structure which do not contain a heteroatom branched from the polyimide precursor main chain, and may be either linear or branched. The portion of the alkylene skeleton constituting a part of the main chain, quaternary carbon constituting a part of the main chain (carbon which is disubstituted and constitutes a part of the main chain), is not included in “aliphatic hydrocarbon group” in calculation of the aliphatic hydrocarbon group concentration. The aliphatic hydrocarbon group constituting the side chain portion branched from the main chain may be saturated or unsaturated, chain or alicyclic, and included in “aliphatic hydrocarbon group” in calculation of the aliphatic hydrocarbon group concentration. Structural examples of “aliphatic hydrocarbon group” include structures represented by the following general formulas (A1), (A2) and (A3).

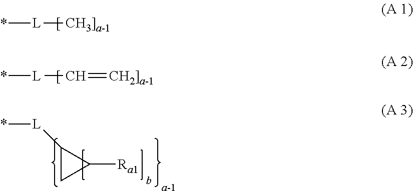

In the general formulas (A1) to (A3), L may be a single bond, or an a-valent organic group which may be either a linear or branched saturated hydrocarbon, or a linear or branched unsaturated hydrocarbon group, b is an integer of 1 to 6, and Rₐ₁ is an organic group having 1 to 8 carbon atoms which may have a ring structure, or a hydrogen atom. * is a connecting group to the main chain structure.

From the viewpoint of the dielectric loss tangent of the cured polyimide film, the aliphatic hydrocarbon group is preferably the above general formula (4) or (6), and from the viewpoint of the chemical resistance, it has 1 to 3 carbon atoms. Preferably, it has, for example, a methyl group. When aliphatic hydrocarbon group concentration T is 4 wt % or more, the dielectric loss tangent of the polyimide cured film tends to be satisfactory. Aliphatic hydrocarbon group concentration T is preferably 5 wt % or more, more preferably 7 wt % or more, and still more preferably 8 wt % or more. When aliphatic hydrocarbon group concentration T is 5 wt % or more, the moisture permeability tends to be satisfactory. Meanwhile, when aliphatic hydrocarbon group concentration T is 35 wt % or less, the resulting polyimide cured film tends to have satisfactory resolution and moisture permeability. Aliphatic hydrocarbon group concentration T is more preferably 28 wt % or less, and still more preferably 17 wt % or less.

Using the molecular weights of the tetracarboxylic dianhydride and the diamine compound used in the preparation of the polyimide precursor, aliphatic hydrocarbon group concentration T is represented by the following formula (I):

[Mw(P)+Mw(Q)]/[Mw(A)+Mw(B)−36]×100 (I)
wherein, in formula (I), Mw(P) represents the sum of molecular weights of aliphatic hydrocarbon groups in the tetracarboxylic dianhydride, Mw(Q) represents the sum of the molecular weights of aliphatic hydrocarbon groups in the diamine compound, Mw(A) represents the molecular weight of the tetracarboxylic dianhydride, and Mw(B) represents the molecular weight of the diamine compound.

When using two or more types of tetracarboxylic dianhydrides and/or diamine compounds, for example, when using two types of tetracarboxylic dianhydrides and two types of diamine compounds, the aliphatic hydrocarbon group concentration is represented by the following formula (II):

[Mw(P1)×a₁+Mw(P2)×a₂+Mw(Q1)×b₁+Mw(Q2)×b₂]/[Mw(A1)×a₁+Mw(A2)×a₂+Mw(B1)×b₁+Mw(B2)×b₂−36]×100 (II)
wherein, in formula (II), Mw(P1) represents the sum of the molecular weights of aliphatic hydrocarbon groups in the first tetracarboxylic dianhydride, Mw(P2) represents the sum of the molecular weights of aliphatic hydrocarbon groups in the second tetracarboxylic dianhydride, Mw(Q1) represents the sum of the molecular weights of aliphatic hydrocarbon groups in the first diamine compound, Mw(Q2) represents the sum of the molecular weights of aliphatic hydrocarbon groups in the second diamine compound, Mw(A1) represents the molecular weight of the first tetracarboxylic dianhydride, Mw(A2) represents the molecular weight of the second tetracarboxylic dianhydride, a₁ represents the content ratio of the first tetracarboxylic dianhydride, a₂ represents the content ratio of the second tetracarboxylic dianhydride, Mw(B1) represents the molecular weight of the first diamine compound, Mw(B2) represents the molecular weight of the second diamine compound, b₁ represents the content ratio of the first diamine compound, b₂ represents the content ratio of the second diamine compound, and a₁, a₂, b₁ and b₂ satisfy a₁+a₂=1, b₁+b₂=1, respectively. When using three or more types of tetracarboxylic dianhydrides and/or diamine compounds, the aliphatic hydrocarbon group concentration can be determined in the same manner. When using tetracarboxylic acid and/or tetracarboxylic acid chloride as starting material(s), the molecular weight of the corresponding tetracarboxylic dianhydride is used for calculation.

### Condition 2

It is also preferable that the polyimide precursor resin preferably satisfy at least two conditions (2-i) and (2-ii) below.
(2-i) In polyimide of a polyimide cured film obtained by heating and curing the photosensitive resin composition at 350° C., aliphatic hydrocarbon group concentration T which is the ratio of the total molecular weight of aliphatic hydrocarbon groups to the molecular weight of repeating units including structures derived from tetracarboxylic dianhydride and a diamine compound, and photosensitive group concentration S which is the ratio of the total molecular weight of photosensitive groups to the molecular weight of repeating units in the polyimide precursor resin (A) satisfy the following formula (1):

−77≤4T−3S≤44 (1)
(2-ii) (A) The polyimide precursor resin has the other reactive unsaturated bonds which are polymerized by heat or light at the resin end, and are different from the reactive unsaturated bond side chain included in the repeating units.

Aliphatic hydrocarbon group concentration T specified in condition (2-i) has the same definition as that of the aliphatic hydrocarbon group concentration specified in the above condition (1-ii). When the polyimide precursor satisfies these conditions (2-i) and (2-ii), it is possible to obtain a high-resolution negative photosensitive resin composition which has low dielectric properties, low moisture permeability and satisfactory chemical resistance.

Using the molecular weights of the tetracarboxylic dianhydride and the diamine compound used in the preparation of the polyimide precursor, the aliphatic hydrocarbon group concentration S is represented by the following formula (I):

[Mw(R)]/[Mw(A)+Mw(B)+Mw(R)−36]×100 (I)
wherein, in formula (I), Mw(R) represents the sum of the molecular weights of compounds having photopolymerizable groups (photopolymerizable group-containing compounds), Mw(A) represents the molecular weight of the tetracarboxylic dianhydride, and Mw(B) represents the molecular weight of the diamine compound.

When using two or more types of tetracarboxylic dianhydrides and/or diamine compounds, calculation is carried out according to the ratio of starting materials in the same manner as in the definition of the above aliphatic hydrocarbon group concentration T.

In the case of a copolymer of a photopolymerizable group-containing compound and a compound containing no photopolymerizable group, the photosensitive group concentration is represented by the following formula (II):

[Mw(R)]/[Mw(A)+Mw(B)+Mw(R)−36]×100 (I)
wherein, in formula (II), Mw(R) represents the sum of the molecular weights of photopolymerizable group-containing compounds, Mw(S) represents the molecular weights of compounds containing no photopolymerizable group, Mw(A) represents the molecular weight of the tetracarboxylic dianhydride, Mw(B) represents the molecular weight of the diamine compound, c₁ represents the content of the photopolymerizable group-containing compound, c₂ represents the content of the compound containing no photopolymerizable group, and c₁ and c₂ satisfy c₁+c₂=1, respectively When using tetracarboxylic acid and/or tetracarboxylic acid chloride as starting material(s), the molecular weight of the corresponding tetracarboxylic dianhydride is used for calculation.

The unsaturated bond structure which is polymerized by heat or light, and is different from the reactive unsaturated bond side chain included in repeating units in the polyimide precursor resin (A) is preferably, for example, at least one selected from a (meth)acrylic group, a vinyl group, an alkenyl group, a cycloalkenyl group, an alkadienyl group, a cycloalkadienyl group, a styryl group and an ethynyl group. From the viewpoint of low dielectric properties, the unsaturated bond structure is preferably at least one selected from a (meth)acrylic group, a vinyl group, an alkenyl group, a cycloalkenyl group, an alkadienyl group, a cycloalkadienyl group and a styryl group, and from the viewpoint of the chemical resistance, a (meth)acrylic group is more preferable. These unsaturated bond structures may be bonded to either the tetracarboxylic dianhydride used during preparation of the polyimide precursor, or the structure derived from the diamine compound.

As the structure derived from the tetracarboxylic dianhydride, for example, an unsaturated bond structure is introduced via an imide group, an amide group and an ester group. As the structure derived from the diamine compound, for example, an unsaturated bond structure is introduced via a urea group and an amide group. Of these bonds, an imide group and a urea group are preferable from the viewpoint of low dielectric properties. Examples of the polyimide precursor (A) include a polyamide precursor including a structural unit represented by the following general formula (4):

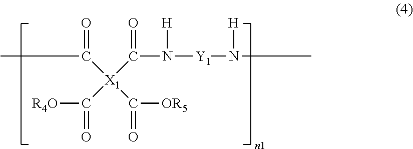

wherein X₁ is a tetravalent organic group having 6 to 40 carbon atoms, Y₁ is a divalent organic group having 6 to 40 carbon atoms, n₁ is an integer of 2 to 150, R₄ and R₅ are each independently a hydrogen atom or a monovalent organic group having 1 to 40 carbon atoms, in which at least one of R₄ and R₅ is a group represented by the following general formula (5):

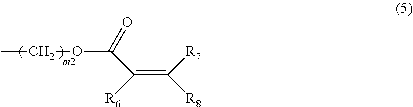

wherein R₆, R₇ and R₈ are each independently a hydrogen atom or a monovalent organic group having 1 to 3 carbon atoms, and m₂ is an integer of 2 to 10. R₄ and R₅ in the general formula (4) is also referred to as a side chain or a side chain structure of the polyimide precursor. R₆ in the general formula (5) is preferably a hydrogen atom or a methyl group, and R₇ and R₈ are preferably a hydrogen atom from the viewpoint of the photosensitive properties. m₂ is preferably an integer of 2 or more and 10 or less, and preferably an integer of 2 or more and 4 or less, from the viewpoint of the photosensitive properties.

From the viewpoint of the resolution and low dielectric properties, the ratio of photosensitive groups per repeating unit in the polyimide precursor resin is preferably 15 wt % to 35 wt %. From the viewpoint of the dielectric properties, the number of photosensitive groups is preferably as small as possible, and from the viewpoint of the resolution, the number of photosensitive groups is preferably as large as possible. As used herein, “ratio of photosensitive groups” has the same definition as that of photosensitive group concentration S specified in condition (2-i), and means the ratio of the molecular weight of the photopolymerizable group-containing compound constituting repeating units based on the molecular weight of the repeating units. Examples of the photopolymerizable group include an unsaturated double bond.

n₁ in the general formula (4) is preferably an integer of 3 to 100, and more preferably an integer of 5 to 70, from the viewpoint of the photosensitive properties and mechanical properties of the photosensitive resin composition.

In the above general formula (4), the tetravalent organic group represented by X₁ is preferably an organic group having 6 to 40 carbon atoms, and more preferably an aromatic group in which —COOR₁ and —COOR₂ groups and a —CONH— group are in the ortho-position to each other, or an alicyclic aliphatic group, in view of achieving both heat resistance and photosensitive properties. Specifically, the tetravalent organic group represented by X₁ include, but is not limited to, an aromatic ring-containing organic group having 6 to 40 carbon atoms, for example, a group having a structure represented by the following general formula (7):

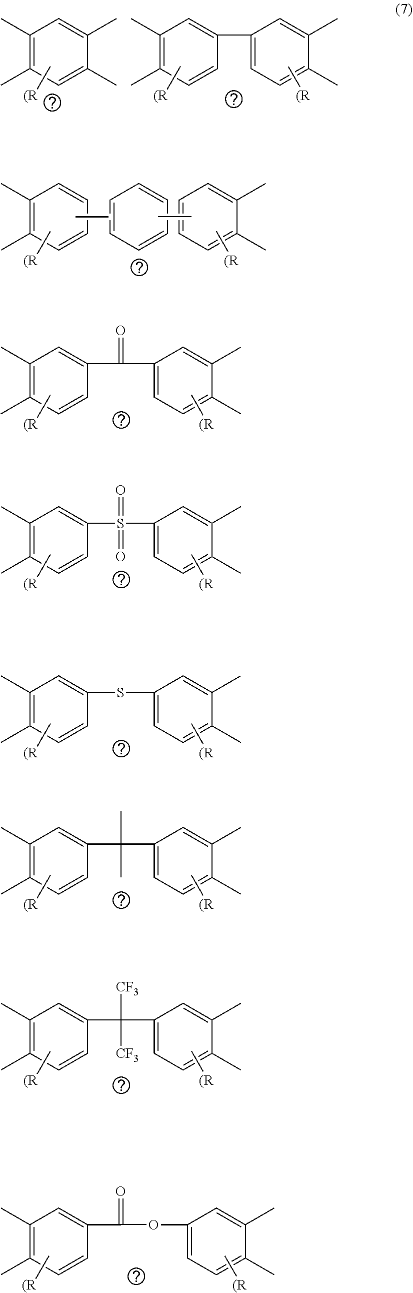

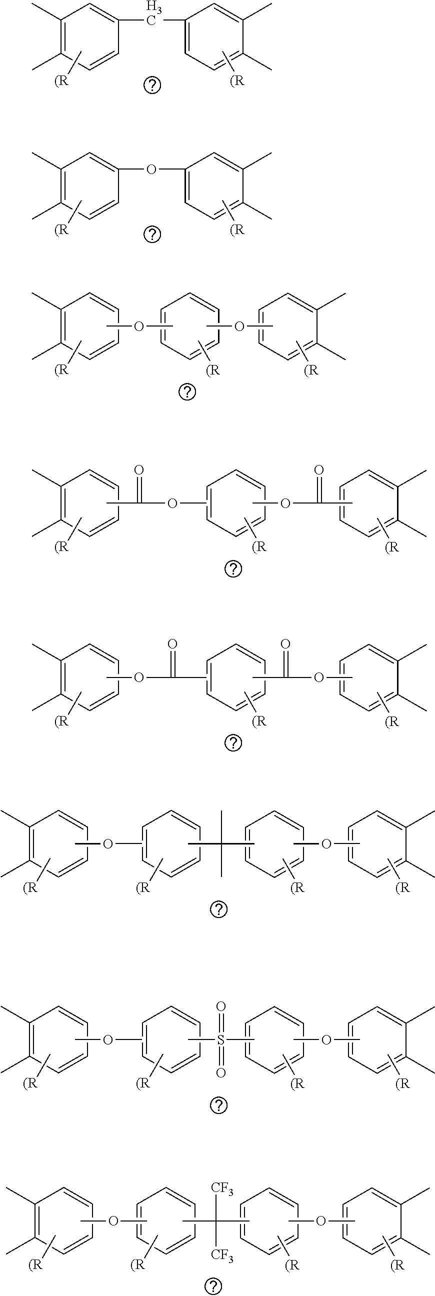

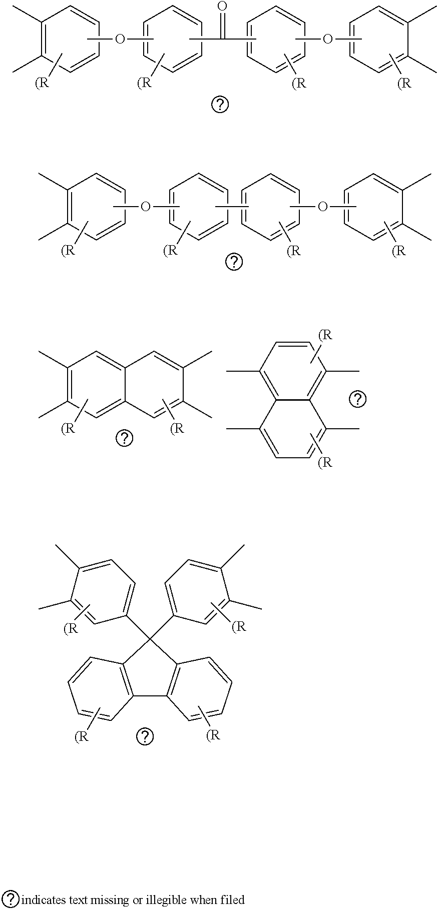

wherein, in formula (7), R₁₁ is a monovalent group selected from the group consisting of a hydrogen atom, a fluorine atom, a C1 to C10 hydrocarbon group and a C1 to C10 fluorine-containing hydrocarbon group, m₅ is an integer of 0 to 2, m₆ is an integer of 0 to 3, and m7 is an integer of 0 to 4. The structure of X₁ may be alone, or a combination of two or more thereof. The X₁ group having a structure represented by the above formula (7) is particularly preferable in view of achieving both heat resistance and photosensitive properties.

In the above general formula (7), the divalent organic group represented by Y₁ is preferably an aromatic group having 6 to 40 carbon atoms in view of achieving both heat resistance and photosensitive properties, and examples thereof include, but are not limited to, a group having a structure represented by the following general formula (8):

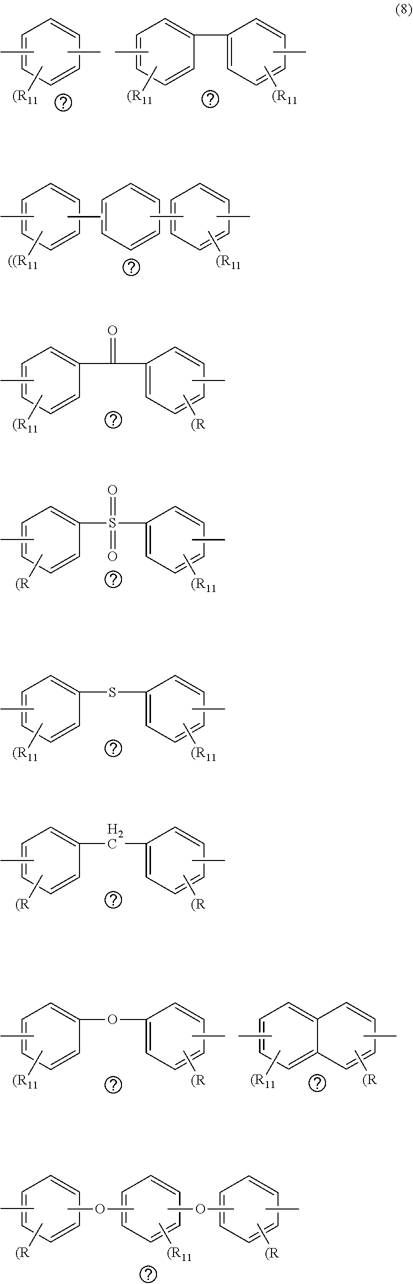

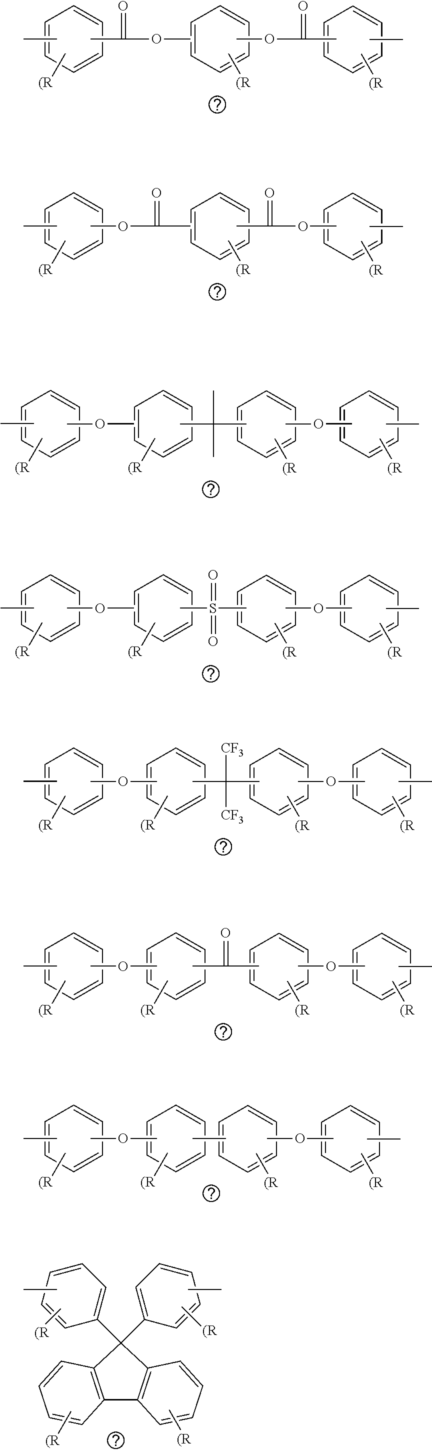

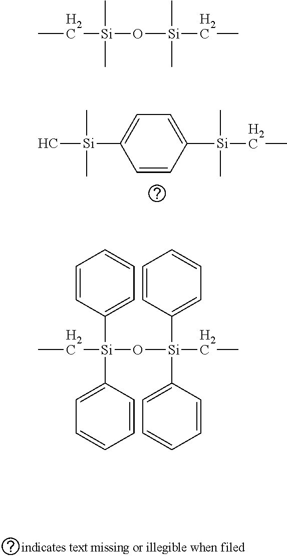

wherein, in formula (8), R₁₁ is a monovalent group selected from the group consisting of a hydrogen atom, a fluorine atom, a C1 to C10 hydrocarbon group and a C1 to C10 fluorine-containing hydrocarbon group, m₅ is an integer of 0 to 2, m₆ is an integer of 0 to 3, and m₇ is an integer of 0 to 4. The structure of Y₁ may be alone, or a combination of two or more thereof. The Y₁ group having a structure represented by the above formula (8) is particularly preferable in view of achieving both heat resistance and photosensitive properties.

From the viewpoint of the resolution, moisture permeability and low dielectric properties, X₁ and/or Y₁ of the polyimide precursor (A) resin specified in the general formula (4) preferably has/have a structure represented by the following general formula (6):

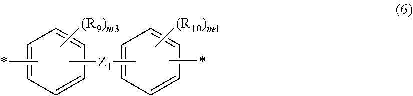

wherein R₉ and R₁₀ are each independently an organic group having 1 to 10 carbon atoms, m3 and m4 are an integer of 1 to 4, Z₁ is selected from the group consisting of a single bond, an organic group having 1 to 30 carbon atoms and an organic group containing a heteroatom, and * means bonding to the main chain of the polyimide precursor resin.

By including the structure of the above general formula (6), it is possible to obtain a cured film which has satisfactory relief pattern resolution and low moisture permeability. By introducing an alkyl chain into the aromatic ring, the solubility of the polyimide precursor in a developing solution is improved and the contrast with the exposed area is easily ensured, leading to an improvement in resolution of the relief pattern. By introducing an organic group into the aromatic ring, the hydrophobicity of the film increases, thus making it difficult for moisture to permeate.

Although the structure of the above general formula (6) is not limited, for example, it preferably includes at least one structure selected from the group consisting of the following general formula (9).

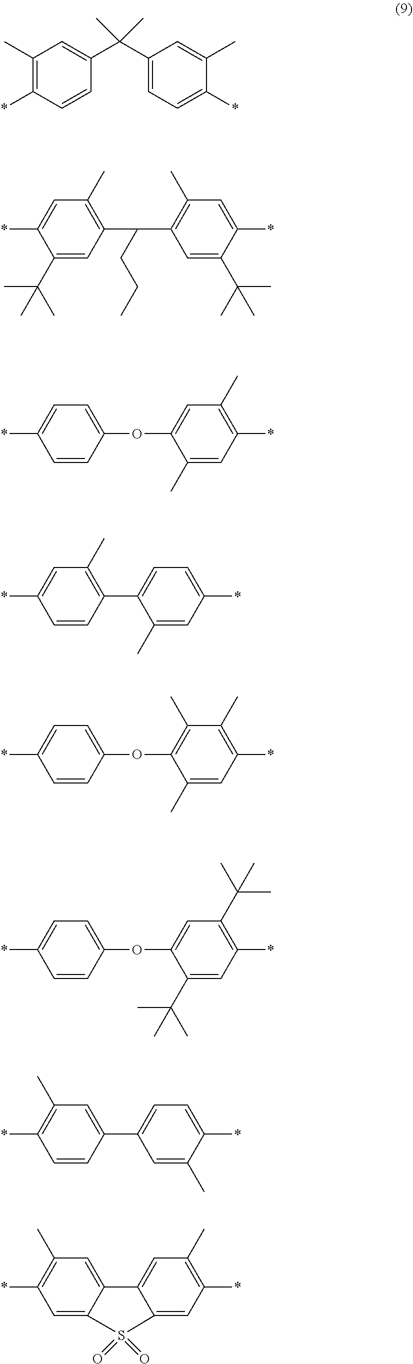

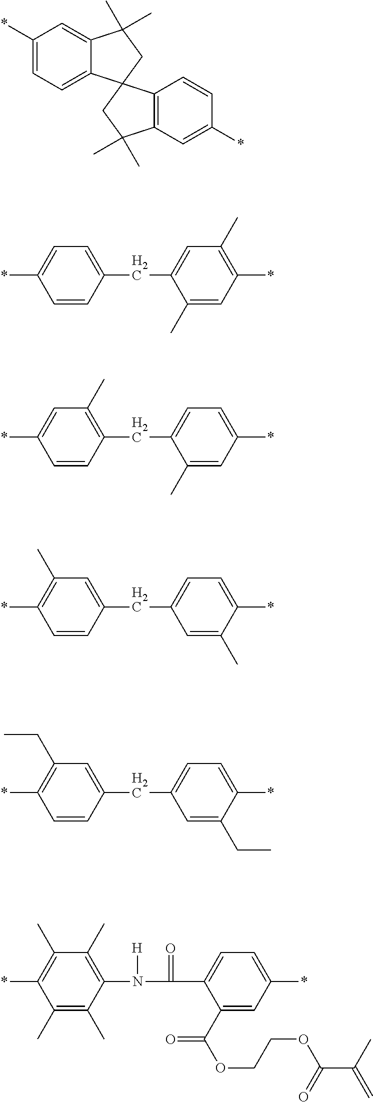

In the above general formula (4), the structure represented by X₁ preferably includes at least one structure selected from the group consisting of the following general formula (10).

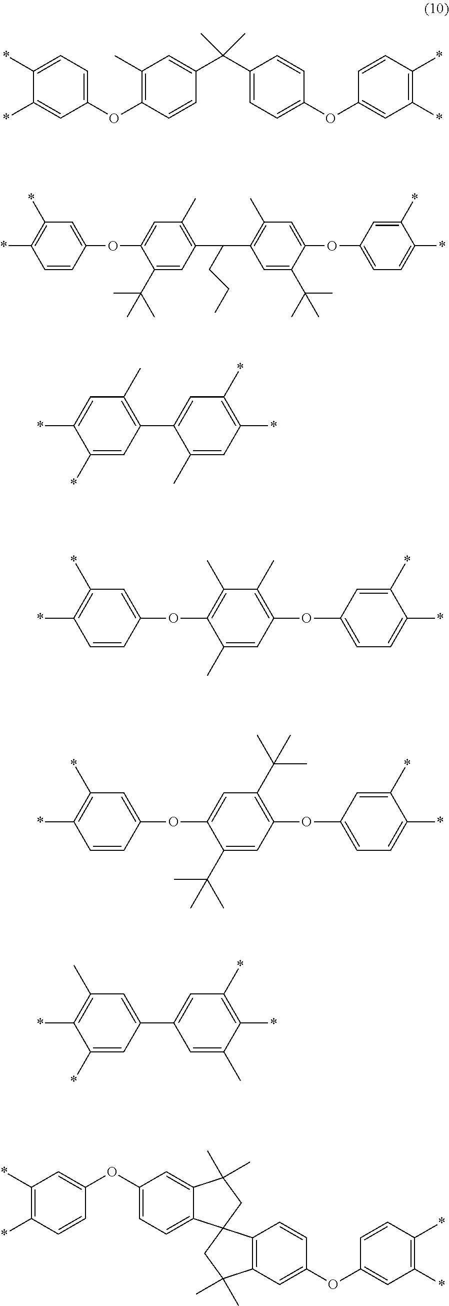

In the above general formula (4), the structure represented by Y₁ preferably includes at least one structure selected from the group consisting of the following general formula (11).

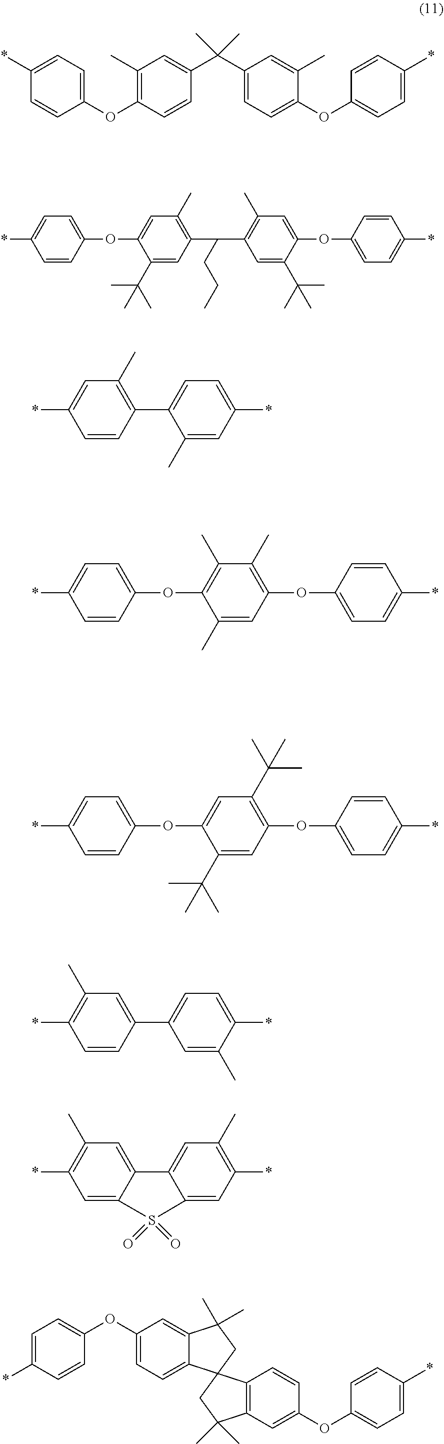

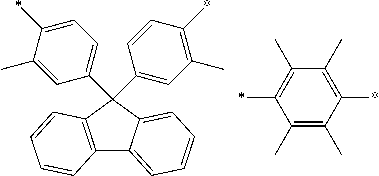

The structure of the above general formula (6) is not limited to the structures shown in (9) to (11) above. The above structures may be alone or a combination of two or more thereof

In the polyimide precursor (A), at least one of X₁ which is a skeleton component derived from a tetracarboxylic acid compound, or Y₁ which is a skeleton component derived from a diamine compound preferably has a structure in which two or more benzene rings are bonded. The number of benzene rings may be 3 or more, 4 or more, 6 or less, 5 or less, or 4 or less, and more preferably 4. When the polyimide precursor (A) has such a structure, the resolution of the negative photosensitive resin composition is maintained, and the resulting cured relief pattern tends to have low dielectric properties.

### Method for Preparing Polyimide Precursor (A)

### Formation of Reactive Terminal Structure

The method of forming a terminal structure having a reactive substituent at the main chain end of the polyimide precursor resin is preferably a synthetic method comprising the following steps:

a monomer preparation step of obtaining an acid component monomer and/or a diamine monomer having a second compound introducing portion by (i) and/or (ii):
(i) reacting tetracarboxylic dianhydride with a first compound having a reactive substituent which reacts with heat or light to generate a first compound introducing portion and carboxyl groups, reacting with a second compound having a reactive substituent which reacts with heat or light, which is different from the first compound, or reacting tetracarboxylic dianhydride with a second compound having a reactive substituent which reacts with heat or light to generate a second compound introducing portion and carboxyl groups, and then reacting with a first compound having a reactive substituent which reacts with heat or light, which is different from the second compound, to obtain an acid component monomer having a second compound introducing portion, and/or
(ii) reacting a diamine compound with a second compound having a reactive substituent which reacts with heat or light to obtain a diamine monomer having a second compound introducing portion; and
a polymerization step of synthesizing a polyimide precursor by subjecting an acid component monomer and/or a diamine monomer having a second compound introducing portion, tetracarboxylic dianhydride and a diamine compound to a condensation reaction. As described above, by using a synthetic method of introducing the second compound into the tetracarboxylic dianhydride and/or the diamine compound before polymerizing the polyimide precursor (hereinafter also referred to as “pre-capping”), the polyimide precursor resin (A) is capable of having a reactive substituent derived from the second compound at the end of the main chain. Examples of the first compound include alcohols having a photopolymerizable group, and examples of the second compound include an isocyanate compound having a photopolymerizable group.

### Preparation of Acid/Ester Body

Examples of the tetracarboxylic dianhydride having a tetravalent organic group X₁ having 6 to 40 carbon atoms, which is suitably used for preparing an ester bond type polyimide precursor, include, but are not limited to, aside from tetracarboxylic dianhydrides derived from the structures described above, for example, pyromellitic anhydride, diphenyl ether-3,3′,4,4′-tetracarboxylic dianhydride, benzophenone-3,3′,4,4′-tetracarboxylic dianhydride, biphenyl-3,3′,4,4′-tetracarboxylic dianhydride, diphenylsulfone-3,3′,4,4′-tetracarboxylic dianhydride, diphenylmethane-3,3′,4,4′-tetracarboxylic dianhydride, 2,2-bis(3,4-phthalic anhydride)propane, 2,2-bis(3,4-phthalic anhydride)-1,1,1,3,3,3-hexafluoropropane, 4,4′-(4,4′-isopropylidenediphenoxy)phthalic anhydride, 4,4′-bis(3,4-dicarboxyphenoxy) benzophenone dianhydride and the like. These may be used alone, or two or more thereof may be used in combination.

Using these tetracarboxylic dianhydrides having a tetravalent organic group X₁ having 6 to 40 carbon atoms, a terminal structure is formed by the introduction method 1 or 2 described above. The order of the reaction varies, depending on the introduction method.

Examples of the compound having a photopolymerizable group (corresponding to the above “second compound”), which is suitably used for synthesis of an esterified tetracarboxylic acid having a reactive end represented by the above general formulas (1) to (3), and introduction of an unsaturated bond structure via a urea bond or an amide bond derived from a diamine compound, include 2-isocyanatoethyl acrylate, 2-isocyanatoethyl methacrylate, 2-(2-methacryloxyoxyethyloxy)ethyl isocyanate, 1,1-(bisacryloyloxymethyl)ethyl isocyanate, allylamine, methacrylic acid chloride, 5-norbornene-2-methylamine and 4-vinylaniline.

Examples of alcohols having a photopolymerizable group (corresponding to the above “second compound”) include 2-hydroxyethyl methacrylate (HEMA), 2-acryloyloxyethyl alcohol, 1-acryloyloxy-3-propyl alcohol, 2-acrylamidoethyl alcohol, methylol vinyl ketone, 2-hydroxyethyl vinyl ketone, 2-hydroxy-3-methoxypropyl acrylate, 2-hydroxy-3-butoxypropyl acrylate, 2-hydroxy-3-phenoxypropyl acrylate, 2-hydroxy-3-butoxypropyl acrylate, 2-hydroxy-3-t-butoxypropyl acrylate, 2-hydroxy-3-cyclohexyloxypropyl acrylate, 2-methacryloxyoxyethyl alcohol, 1-methacryloxyoxy-3-propyl alcohol, 2-metacrylamide ethyl alcohol, 2-hydroxy-3-methoxypropyl methacrylate, 2-hydroxy-3-butoxypropyl methacrylate, 2-hydroxy-3-phenoxypropyl methacrylate, 2-hydroxy-3-butoxypropyl methacrylate, 2-hydroxy-3-t-butoxypropyl methacrylate, 2-hydroxy-3-cyclohexyloxypropyl methacrylate and the like.

The saturated aliphatic alcohols which can be optionally used together with the alcohols having a photopolymerizable group are preferably saturated aliphatic alcohols having 1 to 4 carbon atoms. Specific examples thereof include methanol, ethanol, n-propanol, isopropanol, n-butanol, tert-butanol and the like.

By mixing the above tetracarboxylic dianhydride and alcohol with stirring, preferably in the presence of a basic catalyst such as pyridine, preferably in a suitable reaction solvent, at a temperature of 20 to 50° C. for 4 to 10 hours, the esterification reaction of the acid anhydride proceeds, thus making it possible to obtain a desired acid/ester body.

As the reaction solvent, those capable of completely dissolving the tetracarboxylic dianhydride and alcohol as starting materials as well as the acid/ester body as the product are preferable. More preferably, the solvent also completely dissolves the polyimide precursor which is an amide polycondensation product of the acid/ester body and the diamine. Examples thereof include N-methyl-2-pyrrolidone, N,N-dimethylacetamide, N,N-dimethylformamide, dimethyl sulfoxide, tetramethylurea, ketones, esters, lactones, ethers, halogenated hydrocarbons, hydrocarbons and the like. Specific examples thereof include ketones such as acetone, methyl ethyl ketone, methyl isobutyl ketone and cyclohexanone. Examples of esters include methyl acetate, ethyl acetate, butyl acetate, diethyl oxalate and the like. Examples of lactones include γ-butyrolactone and the like. Examples of ethers include ethylene glycol dimethyl ether, diethylene glycol dimethyl ether, tetrahydrofuran and the like. Examples of halogenated hydrocarbons include dichloromethane, 1,2-dichloroethane, 1,4-dichlorobutane, chlorobenzene, o-dichlorobenzene and the like. Examples of hydrocarbons include hexane, heptane, benzene, toluene, xylene and the like. These may be used alone or in combination of two or more thereof, as necessary.

### Preparation of Polyimide Precursor

An appropriate dehydration condensation agent is added to the acid/ester body (typically in a solution state dissolved in the reaction solvent), preferably under ice cooling, followed by mixing to convert the acid/ester body into a polyanhydride. Then, those obtained separately by dissolving or dispersing diamines having a divalent organic group Y₁ having 6 to 40 carbon atoms in a solvent are added dropwise thereto, and both are subjected to amide polycondensation to obtain a desired polyimide precursor. Diaminosiloxanes may be used together with the diamines having a divalent organic group Y₁. Examples of the dehydration condensation agent include dicyclohexylcarbodiimide, 1-ethoxycarbonyl-2-ethoxy-1,2-dihydroquinoline, 1,1-carbonyldioxy-di-1,2,3-benzotriazole, N,N′-disuccinimidyl carbonate and the like. As described above, a polyacid anhydride as an intermediate is obtained.

Examples of diamines having a divalent organic group Y₁ having 6 to 40 carbon atoms which are suitably used for the reaction with the polyacid anhydride obtained as described above include, aside from diamine derived from the structures described above, for example, p-phenylenediamine, m-phenylenediamine, 4,4-diaminodiphenyl ether, 3,4′-diaminodiphenyl ether, 3,3′-diaminodiphenyl ether, 4,4′-diaminodiphenyl sulfide, 3,4′-diaminodiphenyl sulfide, 3,3′-diaminodiphenyl sulfide, 4,4′-diaminodiphenylsulfone, 3,4′-diaminodiphenylsulfone, 3,3′-diaminodiphenylsulfone, 4,4′-diaminobiphenyl, 3,4′-diaminobiphenyl, 3,3′-diaminobiphenyl, 4,4′-diaminobenzophenone, 3,4′-diaminobenzophenone, 3,3′-diaminobenzophenone, 4,4′-diaminodiphenylmethane, 3,4′-diaminodiphenylmethane, 3,3′-diaminodiphenylmethane, 1,4-bis(4-aminophenoxy)benzene, 1,3-bis(4-aminophenoxy)benzene, 1,3-bis(3-aminophenoxy)benzene, bis[4-(4-aminophenoxy)phenyl]sulfone, bis[4-(3-aminophenoxy)phenyl]sulfone, 4,4-bis(4-aminophenoxy)biphenyl, 4,4-bis(3-5 aminophenoxy)biphenyl, bis[4-(4-aminophenoxy)phenyl]ether, bis[4-(3-aminophenoxy)phenyl]ether, 1,4-bis(4-aminophenyl)benzene, 1,3-bis(4-aminophenyl)benzene, 9,10-bis(4-aminophenyl)anthracene, 2,2-bis(4-aminophenyl)propane, 2,2-bis(4-aminophenyl)hexafluoropropane, 2,2-bis[4-(4-aminophenoxy)phenyl]propane, 2,2-bis [4-(4-aminophenoxy)phenyl]hexafluoropropane, 1,4-bis(3-aminopropyldimethylsilyl)benzene, ortho-tolidine sulfone, 9,9-bis(4-aminophenyl)fluorene, bis{4-(4-aminophenoxy)phenyl}ketone, and those in which a part of hydrogen atoms on the benzene ring are substituted with an alkyl chain such as a methyl group or an ethyl group, for example, 2,2′-dimethyl-4,4′-diaminodiphenylmethane, 3,3′-dimethoxy-4,4′-diaminobiphenyl, 3,3′-dichloro-4,4′-diaminobiphenyl, and mixtures thereof. However, diamines are not limited to the above, and they may be used alone, or in combination of two or more thereof

To improve the adhesion between the photosensitive resin layer formed on the substrate by coating the photosensitive resin composition on the substrate and various substrates, during the preparation of the polyimide precursor (A), it is also possible to copolymerize diaminosiloxanes such as 1,3-bis(3-aminopropyl)tetramethyldisiloxane and 1,3-bis(3-aminopropyl)tetraphenyldisiloxane.

After completion of the amide polycondensation reaction, water-absorbing by-products of the dehydration condensation agent coexisting in the reaction solution are optionally filtered out, and then an appropriate poor solvent (e.g., water, aliphatic lower alcohol, mixed solution thereof, etc.) is added to the solution containing the polymer component to precipitate the polymer component, and as necessary, the polymer is purified by repeating operations such as redissolution and reprecipitation, followed by vacuum drying to isolate the objective polyimide precursor. To improve the degree of purification, the polymer solution may be passed through a column packed with anion and/or cation exchange resins swollen with an appropriate organic solvent to remove ionic impurities.

The weight-average molecular weight of the polyimide precursor (A) is preferably 8,000 to 150,000, more preferably 9,000 to 50,000, and particularly preferably 18,000 to 40,000, when measured as a polystyrene-equivalent weight-average molecular weight by gel permeation chromatography (GPC) from the viewpoint of the heat resistance and mechanical properties of the film obtained after a heat treatment. The weight-average molecular weight is preferably 8,000 or more because of satisfactory mechanical properties, meanwhile, the weight-average molecular weight is preferably 150,000 or less because of satisfactory dispersibility in a developing solution and resolution performance of the relief pattern. Tetrahydrofuran and N-methyl-2-pyrrolidone are recommended as a developing solvent for gel permeation chromatography. The molecular weight is determined from a calibration curve prepared using standard monodisperse polystyrene. It is recommended to select the standard monodisperse polystyrene from an organic solvent-based standard sample STANDARD SM-105 manufactured by Showa Denko K.K.

### (B) Photopolymerization Initiator

The photopolymerization initiator (B) is a compound capable of polymerizing a compound having an ethylenically unsaturated group or the like by generating radicals with active light. Examples of the initiator which generates radicals with active light include compounds including structures such as benzophenone, N-alkylaminoacetophenone, oxime ester, acridine and phosphine oxide. Examples thereof include, but are not limited to, aromatic ketones such as benzophenone, N,N,N′,N′-tetramethyl-4,4′-diaminobenzophenone (Michler's ketone), N,N,N′,N′-tetraethyl-4,4′-diaminobenzophenone, 4-methoxy-4′-dimethylaminobenzophenone, 2-benzyl-2-dimethylamino-1-(morpholinophenyl)-butanone-1,2-methyl-1-[4-(methylthio)phenyl]-2-morpholino-propanone-1, acrylated benzophenone and 4-benzoyl-4′-methyldiphenyl sulfide; benzoin ether compounds such as benzoin methyl ether, benzoin ethyl ether and benzoin phenyl ether; benzoin compounds such as benzoin, methylbenzoin and ethylbenzoin; oxime ester compounds such as 1,2-octanedione, 1-[4-(phenylthio)-, 2-(O-benzoyloxime)], ethanone, 1-[9-ethyl-6-(2-methylbenzoyl)-9H-carbazol-3-yl]-,1-(O-acetyloxime) (Irgacure Oxe02 manufactured by BASF Japan Ltd.), 1-[4-(phenylthio)phenyl]-3-cyclopentylpropane-1,2-dione-2-(o-benzoyloxime) (PBG305 manufactured by Changzhou Tronly New Electronic Materials Co., Ltd.), 1,2-propanedione, 3-cyclohexyl-1-[9-ethyl-6-(2-furanylcarbonyl)-9H-carbazol-3-yl]-,2-(O-acetyloxime) (TR-PBG-326, product name, manufactured by Nikko Chemtech Co., Ltd.); benzyl derivatives such as benzyl dimethyl ketal; acridine derivatives such as 9-phenylacridine and 1,7-bis(9,9′-acridinyl)heptane; N-phenylglycine derivatives such as N-phenylglycine; coumarin compounds; oxazole compounds; and phosphine oxide compounds such as 2,4,6-trimethylbenzoyl-diphenyl-phosphine oxide. The polymerization initiator (C) described above can be used alone or in combination of two or more thereof Of the photopolymerization initiators described above, oxime ester compounds are more preferable from the viewpoint of the resolution. Of these, it is particularly preferable that radical species be derived from a methyl group.

The amount of the photopolymerization initiator mixed is 0.5 part by mass or more and 10 parts by mass or less, preferably 1 part by mass or more and 8 parts by mass or less, relative to 100 parts by mass of the polyimide precursor (A). The mixing amount is 0.5 part by mass or more from the viewpoint of the photosensitivity or patterning properties, meanwhile, the mixing amount is preferably 10 parts by mass or less from the viewpoint of the physical properties of the photosensitive resin layer after curing the photosensitive resin composition.

### (C) Solvent

The solvent (C) is not limited, as long as it can uniformly dissolve or suspend the polyimide precursor (A) and the photopolymerization initiator (B). Examples of such solvent include γ-butyrolactone, dimethyl sulfoxide, tetrahydrofurfuryl alcohol, ethyl acetoacetate, N,N-dimethylacetoacetamide, ε-caprolactone, 1,3-dimethyl-2-imidazolidinone, 3-methoxy-N,N-dimethylpropanamide, 3-butoxy-N,N-dimethylpropanamide, N,N-dimethylformamide, N-methyl-2-pyrrolidone, N-ethyl-2-pyrrolidone, N,N-dimethylacetamide and the like. These solvents may be used alone or in combination of two or more thereof.

The solvent can be used in the amount within a range of, for example, 30 to 1,500 parts by mass, and preferably 100 to 1,000 parts by mass, relative to 100 parts by mass of the polyimide precursor (A) according to the desired coating thickness and viscosity of the photosensitive resin composition. When the solvent includes an alcohol having no olefinic double bond, the content of the alcohol having no olefinic double bond in the total solvent is preferably 5 to 50 wt %, and more preferably 10 to 30 wt %. When the content of the alcohol having no olefinic double bond is 5 wt % or more, the storage stability of the photosensitive resin composition is improved, and when it is 50 wt % or less, the solubility of the polyimide precursor (A) is improved.

### (D) Silane Coupling Agent

To improve the adhesion of the relief pattern, the photosensitive resin composition can optionally include (D) a silane coupling agent. The silane coupling agent (D) preferably has a structure represented by the following general formula (12).

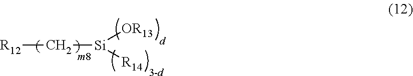

wherein R₁₂ is at least one selected from the group consisting of substituents including an epoxy group, a phenylamino group, a urea group, an isocyanuric group and a ureido group, R₁₃ is each independently represent an alkyl group having 1 to 4 carbon atoms, R₁₄ is a hydroxyl group or an alkyl group having 1 to 4 carbon atoms, d is an integer of 1 to 3, and mg is an integer of 1 to 6.

In the general formula (12), d is not limited, as long as it is an integer of 1 to 3, but is preferably 2 or 3, and more preferably 3, from the viewpoint of the adhesion to the metal rewiring layer. mg is not limited as long as it is an integer of 1 to 6, but is preferably 1 or more and 4 or less from the viewpoint of the adhesion to the metal rewiring layer. From the viewpoint of the developability, it is preferably 2 or more and 5 or less.

R₁₂ is not limited as long as it is a substituent having any one of structures consisting of an epoxy group, a phenylamino group, a urea group, an isocyanuric group and a ureido group. Of these, preferred is at least one selected from the group consisting of a substituent having a phenylamino group, a substituent having a urea group and a substituent having a ureido group, from the viewpoint of the developability and adhesion of the metal rewiring layer, and more preferred is a substituent having a phenylamino group. R₁₃ is not limited, as long as it is an alkyl group having 1 to 4 carbon atoms. Examples thereof include a methyl group, an ethyl group, a propyl group, an isopropyl group, a butyl group, an isobutyl group, a t-butyl group and the like. R₁₄ is not limited, as long as it is a hydroxyl group or an alkyl group having 1 to 4 carbon atoms. Examples of the alkyl group having 1 to 4 carbon atoms include the same alkyl groups as those as for R₁₃

Examples of the epoxy group-containing silane coupling agent include 2-(3,4-epoxycyclohexyl)ethyltrimethoxysilane, 3-glycidoxypropylmethyldimethoxysilane, 3-glycidoxypropyltrimethoxysilane, 3-glycidoxypropyltrimethoxysilane, 3-glycidoxypropylmethyldiethoxysilane, 3-glycidoxypropyltriethoxysilane and the like. Examples of the phenylamino group-containing silane coupling agent include N-phenyl-3-aminopropyltrimethoxysilane. Examples of the ureido group-containing silane coupling agent include 3-ureidopropyltrialkoxysilane. Examples of the isocyanate group-containing silane coupling agent include 3-isocyanatopropyltriethoxysilane.

### (E) Radical Polymerizability Compound

To improve the resolution of the relief pattern, the photosensitive resin composition can optionally include (E) a radically polymerizable compound. Such compound is preferably a (meth)acrylic compound which undergoes a radical polymerization reaction with a photopolymerization initiator, and examples thereof include, but are not particularly limited to, compounds, such as mono- or diacrylate or methacrylate of ethylene glycol or polyethylene glycol, including diethylene glycol dimethacrylate and tetraethylene glycol dimethacrylate, mono-, di- or triacrylate or methacrylate of glycerol, cyclohexane diacrylate or dimethacrylate, diacrylate or dimethacrylate of 1,4-butanediol, diacrylate or dimethacrylate of 1,6-hexanediol, diacrylate or dimethacrylate of neopentyl glycol, mono- or diacrylate or methacrylate of bisphenol A, benzene trimethacrylat, isobornyl acrylate or methacrylate, acrylamide, derivatives thereof, methacrylamide, derivatives thereof, trimethylolpropane triacrylate or methacrylate, di- or tri-acrylate or methacrylate of glycerol, di-, tri- or tetraacrylate or methacrylate of pentaerythritol, and ethylene oxide or propylene oxide adducts of these compounds. These monomers may be used alone, or used as a mixture of two or more thereof.

The amount of the compound having an ethylenically unsaturated double bond mixed is 0.5 part by mass to 15 parts by mass relative to 100 parts by mass of the polyimide precursor (A).

### (F) Thermal Crosslinking Agent

To improve the chemical resistance of the cured film, the photosensitive resin composition can optionally include (F) a thermal crosslinking agent.

The thermal crosslinking agent (F) means a compound which causes an addition reaction or a condensation polymerization reaction by heat. These reactions occur by combinations of the resin (A) and the thermal crosslinking agent (F), the thermal crosslinking agents (F), and the thermal crosslinking agent (F) and other components described later, and the reaction temperature is preferably 150° C. or higher.

The thermal crosslinking agent (F) preferably contains a nitrogen atom. As a result, the interaction with the polyimide resin increases and thus higher chemical resistance can be expected. Examples of the thermal crosslinking agent (F) include alkoxymethyl compounds, epoxy compounds, oxetane compounds, bismaleimide compounds, allyl compounds and blocked isocyanate compounds.

Examples of alkoxymethyl compounds include, but are not limited to, the following compounds.

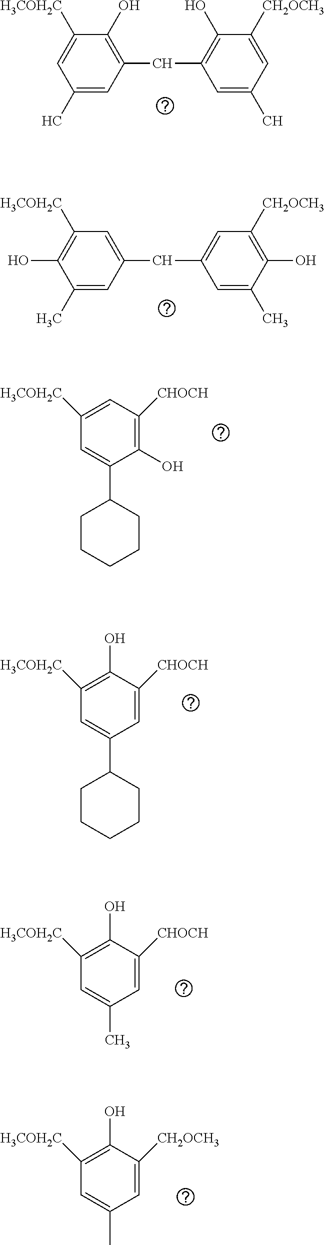

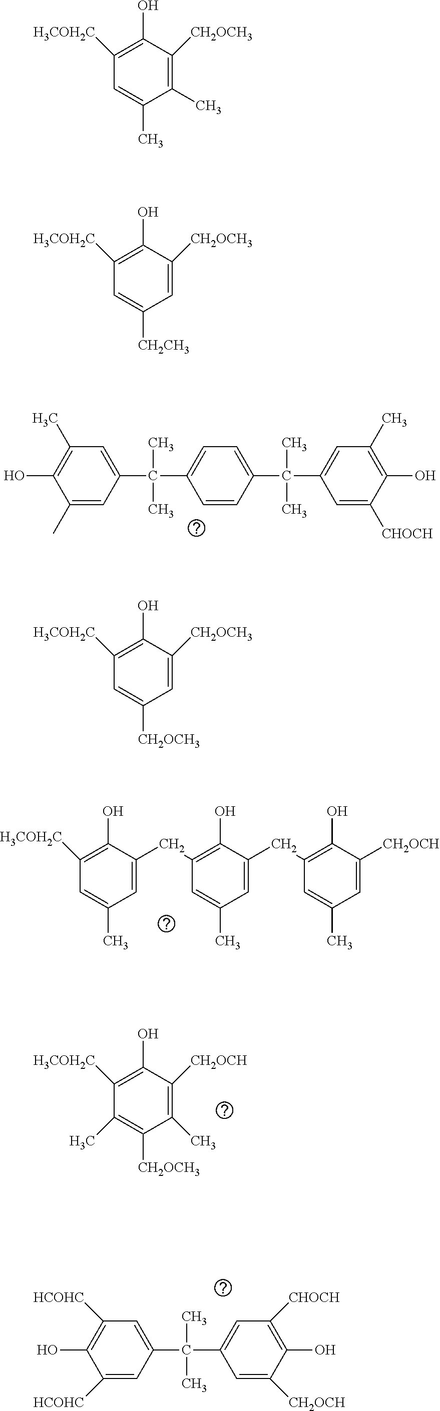

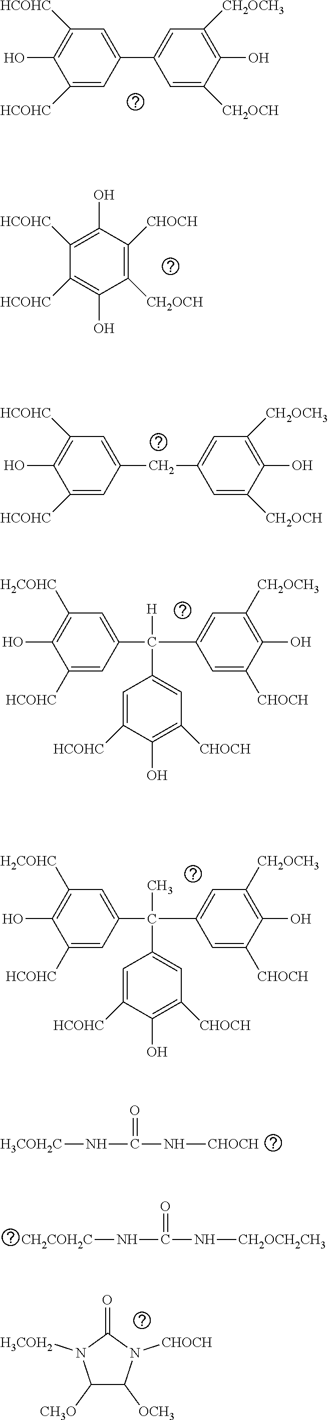

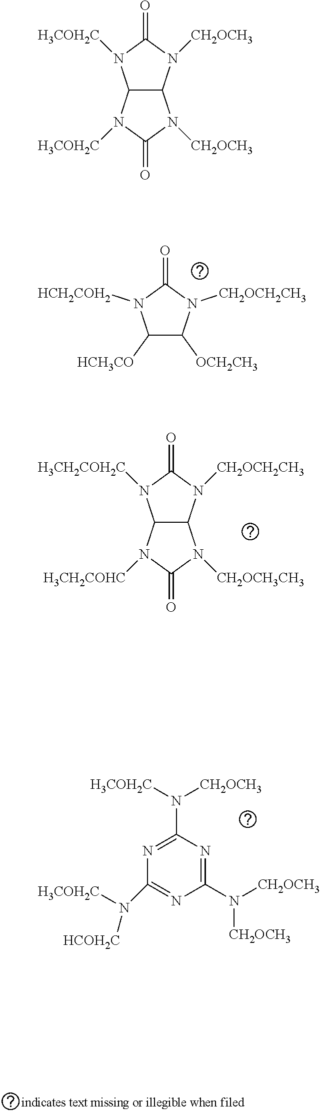

Examples of epoxy compounds include a bisphenol A type group-containing epoxy compound, hydrogenated bisphenol A diglycidyl ether (e.g., Epolite 4000 manufactured by Kyoeisha Chemical Co., Ltd.) and the like. Examples of oxetane compounds include 1,4-bis{[(3-ethyl-3-oxetanyl)methoxy]methyl}benzene, bis[1-ethyl(3-oxetanyl)]methyl ether, 4,4′-bis[(3-ethyl-3-oxetanyl)methyl]biphenyl, 4,4′-bis(3-ethyl-3-oxetanylmethoxy)biphenyl, ethylene glycol bis(3-ethyl-3-oxetanylmethyl)ether, diethylene glycol bis(3-ethyl)-3-oxetanylmethyl)ether, bis(3-ethyl-3-oxetanylmethyl)diphenoate, trimethylolpropane tris(3-ethyl-3-oxetanylmethyl)ether, pentaerythritol tetrakis(3-ethyl-3-oxetanylmethyl)ether, poly[[3-[(3-ethyl-3-oxetanyl)methoxy]propyl]silosesquioxane] derivatives, oxetanyl silicate, phenol novolac type oxetane, 1,3-bis[(3-ethyloxetan-3-yl)methoxy]benzene, OXT121 (trade name, manufactured by TOAGOSEI CO., LTD.), OXT221 (trade name manufactured by TOAGOSEI CO., LTD.) and the like. Examples of bismaleimide compounds include 1,2-bis(maleimido)ethane, 1,3-bis(maleimido)propane, 1,4-bis(maleimido)butane, 1,5-bis(maleimido)pentane, 1,6-bis(maleimido)hexane, 2,2,4-trimethyl-1,6-bis(maleimido)hexane, N,N′-1,3-phenylenebis(maleimide), 4-methyl-N,N′-1,3-phenylenebis(maleimide), N,N′-1,4-phenylenebis(maleimide), 3-methyl-N,N′-1,4-phenylenebis(maleimide), 4,4′-bis(maleimide)diphenylmethane, 3,3′-diethyl-5,5′-dimethyl-4,4′-bis(maleimido)diphenylmethane or 2,2-bis[4-(4-maleimidophenoxy)phenyl]propane. Examples of allyl compounds include allyl alcohol, allylanisole, benzoic acid allyl ester, cinnamic acid allyl ester, N-allyloxyphthalimide, allylphenol, allylphenylsulfone, allyl urea, diallyl phthalate, diallyl isophthalate, diallyl terephthalate, diallyl maleate, diallyl isocyanurate, triallylamine, triallyl isocyanurate, triallyl cyanurate, triallylamine, triallyl 1,3,5-benzenetricarboxylate, triallyl trimellitate, triallyl phosphate, triallyl phosphite, triallyl citrate and the like. Examples of blocked isocyanate compounds include hexamethylene diisocyanate-based blocked isocyanates (e.g., DURANATE SBN-70D, SBB-70P, SBF-70E, TPA-B80E, 17B-60P, MF-B60B, E402-B80B, MF -K60B and WM44-L70G manufactured by Asahi Kasei Co., Ltd., Takenate B-882N,

Baxenden 7960, 7961, 7982, 7991 and 7992 manufactured by Mitsui Chemicals Inc.), tolylene diisocyanate-based blocked isocyanates (e.g., Takenate B-830 manufactured by Mitsui Chemicals Inc.), 4,4′-diphenylmethane diisocyanate-based blocked isocyanates (e.g., Takenate B-815N manufactured by Mitsui Chemicals, and Bronate PMD-OA01 and PMD-MA01 manufactured by TAIEI SANGYO CO., LTD.), 1,3-bis(isocyanatomethyl)cyclohexane-based blocked isocyanates (e.g., Takenate B-846N manufactured by Mitsui Chemicals Inc., Coronate BI-301, 2507 and 2554 manufactured by Tosoh Corporation), and isophorone diisocyanate-based blocked isocyanates (e.g., 7950, 7951 and 7990 manufactured by Baxenden Chemicals Limited). Of these, from the viewpoint of the storage stability, blocked isocyanates and bismaleimide compounds are preferable. The thermal crosslinking agent (F) may be used alone or in combination of two or more thereof.

The content of the thermal crosslinking agent (F) in the resin composition is 0.2 wt % to 40 wt % based on the total solid content of the resin composition, and from the viewpoint of the low dielectric properties and chemical resistance, the content is more preferably 1 wt % to 20 wt %, and still more preferably 2 wt % to 10 wt %.

### (G) Filler

To improve the chemical resistance of the cured film, the photosensitive resin composition can optionally include (G) a filler. The filler is not limited, as long as it is an inert substance added to improve the strength and various other properties.

The filler is preferably particulate from the viewpoint of suppressing an increase in viscosity when the resin composition is prepared. Examples of the particle shape include acicular, plate and spherical shapes. From the viewpoint of suppressing an increase in viscosity when the resin composition is prepared, the filler is preferably spherical.

Examples of the acicular filler include wollastonite, potassium titanate, xonotlite, aluminum borate, acicular calcium carbonate and the like.

Examples of the plate-shaped filler include talc, mica, sericite, glass flake, montmorillonite, boron nitride, plate-shaped calcium carbonate and the like.

Examples of the spherical filler include calcium carbonate, silica, alumina, titanium oxide, clay, hydrotalcite, magnesium hydroxide, zinc oxide, barium titanate and the like. Of these, silica, alumina, titanium oxide and barium titanate are preferable, and silica and alumina are more preferable, from the viewpoint of the electrical properties and storage stability when prepared as a resin composition.

The size of the filler is defined as the primary particle size in the case of a spherical shape, and the length of the long side in the case of a plate or spherical shape, and the size is preferably 5 nm to 1,000 nm, and more preferably 10 nm to 1,000 nm. If the size is 10 nm or more, the resin composition tends to be sufficiently uniform when a resin composition is prepared, and if the size is 1,000 nm or less, the photosensitivity can be imparted. From the viewpoint of imparting photosensitivity, the size is preferably 800 nm or less, more preferably 600 nm or less, and particularly preferably 300 nm or less. From the viewpoint of adhesion and uniformity of the resin composition, the size is preferably 15 nm or more, more preferably 30 nm or more, and particularly preferably 50 nm or more.

The content of the filler (G) in the resin composition is 1% by volume to 20% by volume based on the mass of the resin composition, and from the viewpoint of the dielectric properties, the content is preferably 5% by volume to 20% by volume. From the viewpoint of the resolution, the content is more preferably 5% to 10% by volume.

### Other Components

The photosensitive resin composition may further include components other than the above components (A) to (G). Examples of other components include resin components other than the polyimide precursor (A); organic compounds containing a metal element, sensitizers, thermal polymerization inhibitors, azole compounds and hindered phenol compounds.

The photosensitive resin composition may further include resin components other than the polyimide precursor (A). Examples of resin components which can be included in the photosensitive resin composition include polyimides, polyoxazoles, polyoxazole precursors, phenol resins, polyamides, epoxy resins, siloxane resins, acrylic resins and the like. The amount of these resin components mixed is preferably within a range of 0.01 part by mass to 20 parts by mass relative to 100 parts by mass of the polyimide precursor (A).

The photosensitive resin composition may include an organic compound containing a metal element. The organic compound containing a metal element preferably contains at least one metal element selected from the group consisting of titanium and zirconium in one molecule. It is preferable to contain, as an organic group, a hydrocarbon group and a hydrocarbon group containing a heteroatom. By including an organic compound, the imidization rate of the polyimide precursor included in the photosensitive resin composition increases, leading to a decrease in dielectric loss tangent of the cured film. Examples of the organic titanium or zirconium compounds which can be used include those in which an organic group is bonded to a titanium atom or zirconium atom via a covalent bond or an ionic bond.

Specific examples of the organic titanium or zirconium compound are shown in I) to VII) below:
I) The chelate compound is more preferably a compound having two or more alkoxy groups because of obtaining the storage stability of the photosensitive resin composition and satisfactory pattern. Specific examples of the chelate compound include, but are not limited to, titanium bis(triethanolamine)diisopropoxide, titanium di(n-butoxide) bis(2,4-pentanedionate), titanium diisopropoxide bis(2,4-pentanedionate), titanium diisopropoxide bis(tetramethylheptanedionate), titanium diisopropoxide bis(ethylacetoacetate), and compounds in which the titanium atom of these compounds is substituted with a zirconium atom.
II) Examples of the tetraalkoxy compound include, but are not limited to, titanium tetra(n-butoxide), titanium tetraethoxide, titanium tetra(2-ethylhexoxide), titanium tetraisobutoxide, titanium tetraisopropoxide, titanium tetramethoxide, titanium tetramethoxypropoxide, titanium tetramethylphenoxide, titanium tetra(n-nonyloxide), titanium tetra(n-propoxide), titanium tetrastearyloxide, titanium tetrakis[bis{2,2-(allyloxymethyl)butoxide}], and compounds in which the titanium atom of these compounds is substituted with a zirconium atom.
III) Examples of the titanocene or zirconocene compound include, but are not limited to, pentamethylcyclopentadienyltitanium trimethoxide, bis(η⁵-2,4-cyclopentadien-1-yl)bis(2,6-difluorophenyptitanium, bis(η⁵-2,4-cyclopentadien-1-yl)bis(2,6-difluoro-3-(1H-pyrrol-1-yl)phenyl)titanium, and compounds in which the titanium atom of these compounds is substituted with a zirconium atom.
IV) Examples of the monoalkoxy compound include, but are not limited to, titanium tris(dioctylphosphate)isopropoxide, titanium tris(dodecylbenzenesulfonate)isopropoxide, and compounds in which the titanium atom of these compounds is substituted with a zirconium atom.
V) Examples of the titanium oxide or zirconium oxide compounds include, but are not limited to, titanium oxide bis(pentanedionate), titanium oxide bis(tetramethylheptanedionate), phthalocyanine titanium oxide, and compounds in which the titanium atom of these compounds are substituted with a zirconium atom.
VI) Examples of the titanium tetraacetylacetonate or zirconium tetraacetylacetonate compound include, but are not limited to, titanium tetraacetylacetonate, and compounds in which the titanium atom of these compounds is substituted with a zirconium atom.
VII) Examples of titanate coupling agent include, but are not limited to, isopropyl tridodecylbenzenesulfonyl titanate.

Of the above Examples I) to VII), the organic titanium compound is preferably at least one compound selected from the group consisting of I) titanium chelate compound, II) tetraalkoxytitanium compound and III) titanocene compound from the viewpoint of exhibiting satisfactory dielectric loss tangent. In particular, titanium diisopropoxide bis(ethylacetoacetate), titanium tetra(n-butoxide) and bis(η⁵-2,4-cyclopentadien-1-yl)bis(2,6-difluoro-3-(1H)-pyrrol-1-yl)phenyl)titanium is preferable.

When the organic titanium or zirconium compound is mixed, the mixing amount is 0.01 to 5 parts by mass, and preferably 0.1 to 3 parts by mass, based on 100 parts by mass of the resin (A). When the mixing amount is 0.01 part by mass or more, satisfactory imidization ratio of the resin composition and dielectric loss tangent of the cured film are exhibited, and when the amount is 10 parts by mass or less, excellent storage stability is exhibited, which is preferable.

When the photosensitive resin composition includes an organic compound containing a metal element, the imidization rate of the polyimide precursor included in the resin composition can be improved, leading to a decrease in dielectric loss tangent of the cured film using the resin composition. Although not bound by theory, the reason for improving the imidization rate of the polyimide precursor is considered that the metal element contained in the organic compound containing a metal element is coordinated to a carbonyl group derived from an ester group and/or a carboxyl group of the polyimide precursor to reduce the electron density of the carbon atom of the carbonyl group, leading to promotion of a ring closure reaction.

The photosensitive resin composition can optionally include a sensitizer to improve the photosensitivity. Examples of the sensitizers include Michler's ketone, 4,4′-bis(diethylamino)benzophenone, 2,5-bis(4′-diethylaminobenzal)cyclopentane, 2,6-bis(4′-diethylaminobenzal)cyclohexanone, 2,6-bis(4′-diethylaminobenzal)-4-methylcyclohexanone, 4,4′-bis(dimethylamino)chalcone, 4,4′-bis(diethylamino)chalcone, p-dimethylamino cinnamylideneindanone, p-dimethyl aminobenzylideneindanone, 2-(p-dimethylaminophenylbiphenylene)-benzothiazole, 2-(p-dimethylaminophenylvinylene)benzothiazole, 2-(p-dimethylaminophenylvinylene)isonaphthothiazole, 1,3-bis(4′-dimethylaminobenzal)acetone, 1,3-bis(4′-diethylaminobenzal)acetone, 3,3′-carbonyl-bis(7-diethylaminocoumarin), 3-acetyl-7-dimethylaminocoumarin, 3-ethoxycarbonyl-7-dimethylaminocoumarin, 3-benzyloxycarbonyl-7-dimethylaminocoumarin, 3-methoxycarbonyl-7-diethylaminocoumarin, 3-ethoxycarbonyl-7-diethylaminocoumarin, N-phenyl-N′-ethylethanolamine, N-phenyldiethanolamine, N-p-tolyldiethanolamine, N-phenylethanolamine, 4-morpholinobenzophenone, isoamyl dimethylaminobenzoate, isoamyl diethylaminobenzoate, 2-mercaptobenzimidazole, 1-phenyl-5-mercaptotetrazole, 2-mercaptobenzothiazole, 2-(p-dimethyl aminostyryl)benzoxazole, 2-(p-dimethylaminostyryl)benzthiazole, 2-(p-dimethylaminostyryl)naphtho(1,2-d)thiazole, 2-(p-dimethylaminobenzoyl)styrene and the like. These can be used alone or in combination of a plurality (for example, 2 to 5 types) thereof. The mixing amount of the sensitizer is preferably 0.1 to 25 parts by mass relative to 100 parts by mass of the polyimide precursor (A).

The photosensitive resin composition may optionally include a thermal polymerization inhibitor to improve the viscosity and the stability of the photosensitivity of the photosensitive resin composition during storage in a state of a solvent-containing solution. Examples of the thermal polymerization inhibitor include hydroquinone, N-nitrosodiphenylamine, p-tert-butylcatechol, phenothiazine, N-phenylnaphthylamine, ethylenediaminetetraacetic acid, 1,2-cyclohexanediaminetetraacetic acid, glycol etherdiaminetetraacetic acid, 2,6-di-tert-butyl-p-methylphenol, 5-nitroso-8-hydroxyquinoline, 1-nitroso-2-naphthol, 2-nitroso-1-naphthol, 2-nitroso-5-(N-ethyl-N-sulfopropylamino)phenol, N-nitroso-N-phenylhydroxylamine ammonium salt, N-nitroso-N(1-naphthyl)hydroxylamine ammonium salt and the like. These thermal polymerization inhibitors may be used alone or in combination of two or more thereof. The content of the thermal polymerization inhibitor is preferably within a range of 0.005 part by mass to 12 parts by mass relative to 100 parts by mass of the polyimide precursor (A).

The photosensitive resin composition can optionally include an azole compound to suppress discoloration of the substrate when using a substrate made of copper or a copper alloy. Examples of the azole compound include 1H-triazole, 5-methyl-1H-triazole, 5-ethyl-1H-triazole, 4,5-dimethyl-1H-triazole, 5-phenyl-1H-triazole, 4-t-butyl-5-phenyl-1H-triazole, 5-hydroxyphenyl-1H-triazole, phenyltriazole, p-ethoxyphenyltriazole, 5-phenyl-1-(2-dimethylaminoethyl)triazole, 5-benzyl-1H-triazole, hydroxyphenyltriazole, 1,5-dimethyltriazole, 4,5-diethyl-1H-triazole, 1H-benzotriazole, 2-(5-methyl-2-hydroxyphenyl)benzotriazole, 2-[2-hydroxy-3,5-bis(α,α-dimethylbenzyl)phenyl]-benzotriazole, 2-(3,5-di-t-butyl-2-hydroxyphenyl)benzotriazole, 2-(3-t-butyl-5-methyl-2-hydroxyphenyl)-benzotriazole, 2-(3,5-di-t-amyl-2-hydroxyphenyl)benzotriazole, 2-(2′-hydroxy-5′-t-octylphenyl)benzotriazole, hydroxyphenylbenzotriazole, tolyltriazole, 5-methyl-1H-benzotriazole, 4-methyl-1H-benzotriazole, 4-carboxy-1H-benzotriazole, 5-carboxy-1H-benzotriazole, 1H-tetrazole, 5-methyl-1H-tetrazole, 5-phenyl-1H-tetrazole, 5-amino-1H-tetrazole, 1-methyl-1H-tetrazole and the like. In particular, tolyltriazole, 5-methyl-1H-benzotriazole and 4-methyl-1H-benzotriazole are preferable. These azole compounds may be used alone, or used as a mixture of two or more thereof.

The amount of the azole compound mixed is preferably 0.1 part by mass to 20 parts by mass relative to 100 parts by mass of the polyimide precursor (A), and is more preferably 0.5 part by mass to 5 parts by mas from the viewpoint of the photosensitive properties. If the mixing amount of the azole compound relative to 100 parts by mass of the polyimide precursor (A) is 0.1 part by mass or more, when the photosensitive resin composition is formed on copper or a copper alloy, discoloration of the surface of copper or a copper alloy is suppressed, meanwhile, the mixing amount is preferably 20 parts by mass or less because of excellent in photosensitivity.

The photosensitive resin composition may include a hindered phenol compound to suppress discoloration of the substrate when using a substrate made of copper or a copper alloy. Examples of the hindered phenol compounds include, but are not limited to, 2,6-di-t-butyl-4-methylphenol, 2,5-di-t-butyl-hydroquinone, octadecyl-3-(3,5-di-t-butyl-4-hydroxyphenyl)propionate, isooctyl-3-(3,5-di-t-butyl-4-hydroxyphenyl)propionate, 4,4′-methylenebis(2,6-di-t-butylphenol), 4,4′-thio-bis(3-methyl-6-t-butylphenol), 4,4′-butylidene-bis(3-methyl-6-t-butylphenol), triethyleneglycol-bis[3-(3-t-butyl-5-methyl-4-hydroxyphenyl)propionate], 1,6-hexanediol-bis[3-(3,5-di-t-butyl-4-hydroxyphenyl)propionate], 2,2-thio-diethylenebis[3-(3,5-di-t-butyl-4-hydroxyphenyl)propionate], N,N′-hexamethylenebis(3,5-di-t-butyl-4-hydroxy-hydrocinnamamide), 2,2′-methylene-bis(4-methyl-6-t-butylphenol), 2,2′-methylene-bis(4-ethyl-6-t-butylphenol), pentaerithrityl-tetrakis[3-(3,5-di-t-butyl-4-hydroxyphenyl)propionate], tris-(3,5-di-t-butyl-4-hydroxybenzyl)-isocyanurate, 1,3,5-trimethyl-2,4,6-tris(3,5-di-t-butyl-4-hydroxybenzyl)benzene, 1,3,5-tris(3-hydroxy-2,6-dimethyl-4-isopropylbenzyl)-1,3,5-triazine-2,4,6-(1H,3H,5H)-trione, 1,3,5-tris(4-t-butyl-3-hydroxy-2,6-dimethylbenzyl)-1,3,5-triazine-2,4,6-(1H,3H,5H)-trione, 1,3,5-tris(4-s-butyl-3-hydroxy-2,6-dimethylbenzyl)-1,3,5-triazine-2,4,6-(1H,3H,5H)-trione, 1,3,5-tris[4-(1-ethylpropyl)-3-hydroxy-2,6-dimethylbenzyl]-1,3,5-triazine-2,4,6-(1H,3H,5H)-trione, 1,3,5-tris[4-triethylmethyl-3-hydroxy-2,6-dimethylbenzyl]-1,3,5-triazine-2,4,6-(1H,3H,5H)-trione, 1,3,5-tris(3-hydroxy-2,6-dimethyl-4-phenylbenzyl)-1,3,5-triazine-2,4,6-(1H,3H,5H)-trione, 1,3,5-tris(4-t-butyl-3-hydroxy-2,5,6-trimethylbenzyl)-1,3,5-triazine-2,4,6-(1H,3H,5H)-trione, 1,3,5-tris(4-t-butyl-5-ethyl-3-hydroxy-2,6-dimethylbenzyl)-1,3,5-triazine-2,4,6-(1H,3H,5H)-trione, 1,3,5-tris(4-t-butyl-6-ethyl-3-hydroxy-2-methylbenzyl)-1,3,5-triazine-2,4,6-(1H,3H,5H)-trione, 1,3,5-tris(4-t-butyl-6-ethyl-3-hydroxy-2,5-dimethylbenzyl)-1,3,5-triazine-2,4,6-(1H,3H,5H)-trione, 1,3,5-tris(4-t-butyl-5,6-diethyl-3-hydroxy-2-methylbenzyl)-1,3,5-triazine-2,4,6-(1H,3H,5H)-trione, 1,3,5-tris(4-t-butyl-3-hydroxy-2-methylbenzyl)-1,3,5-triazine-2,4,6-(1H,3H,5H)-trione, 1,3,5-tris(4-t-butyl-3-hydroxy-2,5-dimethylbenzyl)-1,3,5- triazine-2,4,6-(1H,3H,5H)-trione, 1,3,5-tris(4-t-butyl-5-ethyl-3-hydroxy-2-methylbenzyl)-1,3,5-triazine-2,4,6-(1H,3H,5H)-trione and the like. Of these, 1,3,5-tris(4-t-butyl-3-hydroxy-2,6-dimethylbenzyl)-1,3,5-triazine-2,4,6-(1H,3H,5H)-trione is particularly preferable.

The amount of the hindered phenol compound mixed is preferably 0.1 part by mass to 20 parts by mass relative to 100 parts by mass of the polyimide precursor (A), and is more preferably 0.5 part by mass to 10 parts by mass from the viewpoint of the photosensitive properties. If the amount of the hindered phenol compound (A) mixed relative to 100 parts by mass of the polyimide precursor is 0.1 part by mass or more, for example, when the photosensitive resin composition is formed on copper or a copper alloy, discoloration and corrosion of copper or a copper alloy are prevented, meanwhile, the amount is preferably 20 parts by mass or less, because of excellent in photosensitivity.

### Polyimide Cured Film and Method for Producing Same

The present disclosure also provides a method for producing a polyimide cured film, which comprises a step of converting a photosensitive resin composition into polyimide. The method for producing a cured polyimide film of the present disclosure comprises, for example, the following steps (1) to (5):
(1) a step of applying the photosensitive resin composition of the present disclosure on a substrate to form a photosensitive resin layer on the substrate;
(2) a step of heating and drying the obtained photosensitive resin layer;
(3) a step of exposing the heat-dried photosensitive resin layer;
(4) a step of developing the exposed photosensitive resin layer; and
(5) a step of heat-treating the developed photosensitive resin layer to form a polyimide cured film.

The photosensitive resin composition used in the method for producing a cured film preferably contains 100 parts by mass of a polyimide precursor, 0.5 to 10 parts by mass of a photosensitizing agent, and 100 to 300 parts by mass of a solvent. It is more preferable that a photoradical polymerization initiator be contained as the photosensitizing agent, and it is still more preferable that the photosensitive resin composition is of a negative photosensitive resin composition.

Specific steps in the method for producing a cured film can be carried out according to steps (1) to (5) of the method for producing a cured film described above. Typical aspects of each step will be described below.

### (1) Step of Applying a Photosensitive Resin Composition on a Substrate to form a Photosensitive Resin Layer on the Substrate

In this step, the photosensitive resin composition of the present disclosure is applied on a substrate, and as necessary, it is then dried to form a photosensitive resin layer. It is possible to use, as the coating method, a method conventionally used for coating a photosensitive resin composition, for example, a method of coating with a spin coater, a bar coater, a blade coater, a curtain coater, a screen printer or the like, or a method of spray-coating with a spray coater.

### (2) Step of Heating and Drying the Obtained Photosensitive Resin Layer

As necessary, the photosensitive resin composition film can be heated and dried. It is possible to use, as the drying method, methods such as air drying, heat drying using an oven or a hot plate, and vacuum drying. The coating film is preferably dried under such conditions that imidization of the polyimide precursor (A) (polyamic acid ester) in the photosensitive resin composition does not occur. Specifically, when air drying or heat drying is carried out, drying can be carried out at 20° C. to 140° C. for 1 minute to 1 hour. As described above, a photosensitive resin layer can be formed on the substrate.

### (3) Step of Exposing the Heat-Dried Photosensitive Resin Layer

In this step, the photosensitive resin layer thus formed is exposed. It is possible to use, as the exposure device, for example, a contact aligner, a mirror projection, a stepper and the like. Exposure can be carried out through a patterned photomask or reticle, or carried out directly. Light used for exposure is, for example, an ultraviolet light source or the like.

After exposure, for the purpose of improving the photosensitivity or the like, post exposure bake (PEB) and/or pre-development bake may be carried out at any combination of temperature and time, as necessary. The range of bake conditions is preferably as follows: the temperature is within a range of 40 to 120° C. and the time is within a range of 10 seconds to 240 seconds, but is not limited to the above range as long as it does not interfere with various properties of the negative photosensitive resin composition of the present embodiment.

### (4) Step of Developing the Exposed Photosensitive Resin Layer

In this step, the exposed photosensitive resin layer is developed to form a relief pattern. When the photosensitive resin composition is of a negative photosensitive resin composition, the unexposed area of the exposed photosensitive resin layer is removed by development. It is possible to use, as the method of developing a photosensitive resin layer after exposure (irradiation), any method selected from conventionally known method of developing a photoresist, such as a rotary spray method, a paddle method and an immersion method accompanied by an ultrasonic treatment. After development, for the purpose of adjusting the shape of the relief pattern or the like, post-development bake may be carried out at any combination of temperature and time, as necessary. A developing solution used for development is preferably, for example, a good solvent for a negative photosensitive resin composition, or a combination of the good solvent and a poor solvent. Examples of the good solvent include N-methyl-2-pyrrolidone, N-cyclohexyl-2-pyrrolidone, N,N-dimethylacetamide, cyclopentanone, cyclohexanone, y-butyrolactone, a-acetyl-y-butyrolactone and the like. Preferred examples of the poor solvent include toluene, xylene, methanol, ethanol, isopropyl alcohol, ethyl lactate, propylene glycol methyl ether acetate and water. When the good solvent and the poor solvent are used as a mixture, it is preferable to adjust the ratio of the poor solvent to the good solvent according to the solubility of the polymer in the negative photosensitive resin composition. It is also possible to use two or more types, for example, several types of solvents in combination. In the step of developing the exposed photosensitive resin layer, it is preferable to carry out coating to development steps to obtain a photosensitive resin layer having a thickness of 10 μm to 15 μm. The developing time is preferably 30 seconds or less, more preferably 25 seconds or less, and still more preferably 20 seconds or less. Although not bound by theory, when the developing time is 30 seconds or less, a difference in solubility with respect to the exposed area is generated, thus providing a contrast and improving the resolution of the pattern.

### (5) Step of Heat-Treating the Developed Photosensitive Resin Layer to Form a Polyimide Cured Film

In this step, the relief pattern obtained by the above development is heated to dilute the photosensitive component, and the polyimide precursor (A) is imidized to convert into a cured relief pattern made of polyimide. It is possible to select, as the heat curing method, various methods such as a method using a hot plate, a method using an oven, and a method using a heating oven capable of setting a temperature program. Heating can be carried out, for example, at 160° C. to 400° C. for 30 minutes to 5 hours. It is possible to use, as the atmospheric gas for heat curing, either air, or an inert gas such as nitrogen or argon. A cured relief pattern (cured polyimide film) can be produced in the manner described above.

The method for producing a polyimide cured film of the present disclosure comprises, for example, applying the resin composition on a substrate, and subjecting the substrate to an exposure treatment, a development treatment and then a heat treatment, and the cured film preferably has a dielectric loss tangent within a range of 0.003 to 0.012 as measured at 40 GHz by the perturbation type split cylinder resonator method. The dielectric loss tangent can be measured by the perturbation type split cylinder resonator method shown in Examples below.

The present disclosure also provides a cured polyimide film obtained from the photosensitive resin composition described above. The cured film preferably has moisture permeability of less than 800, and more preferably less than 700. From the viewpoint of the dielectric loss tangent, the lower the moisture permeability, the better, since the frequency dependence of dielectric loss tangent tends to be less. Meanwhile, from the viewpoint of the resolution, the lower the moisture permeability, the more the solubility of the unexposed area during patterning deteriorates, leading to deterioration of the resolution. Therefore, the moisture permeability is more preferably 500 or more and less than 800. When the moisture permeability is less than 800, a cured film with high reliability can be obtained. See below for details on measuring the moisture permeability. From the viewpoint of frequency dependence in resolution, dielectric properties and dielectric loss tangent, the product of dielectric loss tangent and moisture permeability (tan δ₄₀×WVTR) is preferably within a certain range, and when a dielectric loss tangent value at 40 GHz is used, and the moisture permeability preferably satisfies the following formula (2):

3.0<tan δ₄₀×WVTR<10.0 (2)
When tan δ₄₀×WVTR is within a range of 3.0 to 10.0, it is possible to obtain a cured polyimide product having excellent resolution and dielectric properties and less frequency dependence. The difference in dielectric loss tangent at between 40 GHz and 10 GHz is preferably 0.0015 or less, and more preferably 0.001 or less.

Regarding the polyimide cured film obtained in the present disclosure, from the viewpoint of achieving both dielectric loss tangent and chemical resistance, the product of the dielectric loss tangent and the dissolution rate of the cured film dissolved in a chemical solution during a chemical resistance test (tan δ₄₀×WVTR×DR) is preferably within a certain range, and when using the value of the dielectric loss tangent at 40 GHz, the product preferably satisfies the following formula (3):

4.0<tan δ₄₀×WVTR×DR<29.0 (3)
When tan δ₄₀×WVTR×DR is within a range of 4.0 to 29.0, it is possible to obtain a polyimide cured material having excellent dielectric properties and chemical resistance, and less frequency dependence.

### Semiconductor Device

The present disclosure can also provide a semiconductor device having a cured relief pattern obtained by the method for producing a cured relief pattern described above using the photosensitive resin composition of the present disclosure. Accordingly, there is provided a semiconductor device comprising a base material which is a semiconductor element and a cured relief pattern of polyimide formed on the base material by the above method for producing a cured relief pattern. The present disclosure can also be applied to a method for producing a semiconductor device which uses a semiconductor element as the base material and includes the above method for producing a cured relief pattern as part of the steps. The semiconductor device can be produced by forming the cured relief pattern formed by the above method for producing a cured relief pattern as a surface protective film, an interlayer insulating film, an insulating film for rewiring, a protective film for a flip chip device, or a protective film for a semiconductor device having a bump structure, and combining with a known method for producing a semiconductor device.

The polyimide contained in the cured relief pattern (cured polyimide film) formed from the polyimide precursor composition preferably has a structure represented by the following general formula (13):

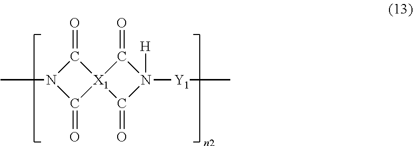

wherein, in the general formula (13), X₁ and Y₁ are the same as X₁ and Y₁ in the above general formula (4), and n₂ is an integer of 2 to 150.

### Display Device

The present disclosure can also provide a display device comprising a display element and a cured film provided on top of the display element using the photosensitive resin composition of the present disclosure, wherein the cured film is the cured relief pattern. Here, the cured relief pattern may be laminated in direct contact with the display element, or may be laminated with another layer interposed therebetween. Examples of the cured film include a surface protective film, an insulating film and a planarizing film for TFT liquid crystal display elements and color filter elements, projections for MVA type liquid crystal display devices, and barrier ribs for cathodes of organic EL devices.

The photosensitive resin composition of the present disclosure is also useful for applications such as interlayer insulation of multilayer circuits, cover coats for flexible copper-clad plates, solder resist films and liquid crystal alignment films, in addition to application to the semiconductor device as described above.

### Method for Producing Photosensitive Resin Composition

The method for producing a photosensitive resin composition of the present disclosure is a method for producing a photosensitive resin composition comprising (A) 100 parts by mass of a polyimide precursor resin, (B) 0.5 to 10 parts by mass of a photopolymerization initiator, and (C) 50 to 500 parts by mass of a solvent. The method comprises a step of synthesizing the polyimide precursor resin (A) and a step of mixing the polyimide precursor resin (A), the photopolymerization initiator (B) and the solvent (C) to obtain a photosensitive resin composition. The synthesis step comprises the following steps:
a monomer preparation step of obtaining an acid component monomer and/or a diamine monomer having a second compound introducing portion by (i) and/or (ii):
(i) reacting tetracarboxylic dianhydride with a first compound having a reactive substituent which reacts with heat or light to generate a first compound introducing portion and carboxyl groups, reacting with a second compound having a reactive substituent which reacts with heat or light, which is different from the first compound, or reacting tetracarboxylic dianhydride with a second compound having a reactive substituent which reacts with heat or light to generate a second compound introducing portion and carboxyl groups, and then reacting with a first compound having a reactive substituent which reacts with heat or light, which is different from the second compound, to obtain an acid component monomer having a second compound introducing portion, and/or
(ii) reacting a diamine compound with a second compound having a reactive substituent which reacts with heat or light to obtain a diamine monomer having a second compound introducing portion; and
a polymerization step of synthesizing a polyimide precursor by subjecting an acid component monomer and/or a diamine monomer having a second compound introducing portion, tetracarboxylic dianhydride and a diamine compound to a condensation reaction.

As described above, by using a synthetic method of introducing the second compound into the tetracarboxylic dianhydride and/or the diamine compound before polymerizing the polyimide precursor (hereinafter also referred to as “pre-capping”), the polyimide precursor resin (A) can have a reactive substituent derived from the second compound at the end of the main chain. In this production method, when a compound having a desired structure is reacted in advance with a starting material (monomer) before polymerization, the resin end can be formed efficiently compared with the case where a sealing reaction is carried out on the resin end after polymerization (hereinafter also referred to as “post-capping”).

As used herein, the ratio of the number of mols of reactive substituents bonded per unit molar amount of carboxylic acid groups derived from the tetracarboxylic dianhydride located at the main chain end, or unit molar amount of amine groups derived from the diamine compound located at the main chain end of the polyimide precursor resin (A) is called “capping ratio”. A comparison of the capping ratio can be carried out by ¹H-NMR. In other words, when the area of the aromatic amide peak (around 10.0 ppm to 11.0 ppm) derived from the main chain is 1.0, the proton peak (5.0 ppm to 6.5 ppm) of polymerizable functional groups derived from the terminal structure is defined as “end-capping value”, and it is possible to compare the capping ratio by comparing them. In case where the proton peak of polymerizable functional groups derived from the repeating structure and other peaks unrelated to the polymerizable functional groups are confirmed around 5.0 ppm to 6.5 ppm where the proton peak of the polymerizable functional groups derived from the terminal structure appears, these proton peaks are excluded from calculation of “end-capping value”.

Comparing pre-capping and post-capping, the pre-capping tends to have a higher peak intensity than that of the post-capping. Although not bound by theory, the reason for this is considered as follows: in the pre-capping, the reaction rate is high due to the reaction between monomers (low molecular weight), whereas, in the post-capping, the active end is deactivated during polymerization and the reaction occurs between polymer (high molecular weight) and a monomer (low molecular weight), leading to low reaction rate.

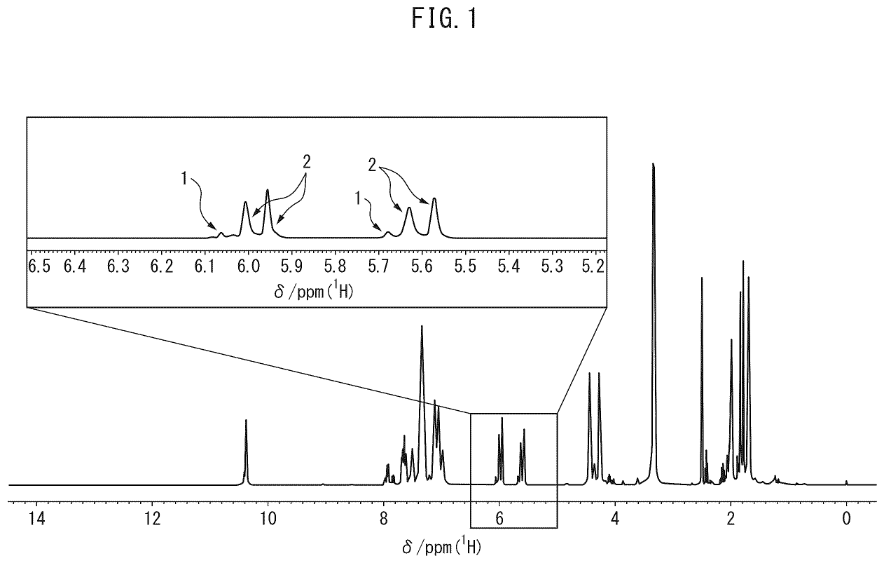

For example, FIG. 1 is an example of ¹H-NMR of a polyimide precursor resin in which carboxylic acid groups derived from tetracarboxylic dianhydrides located at the end of the main chain are pre-capped. In the case of ¹H-NMR shown in FIG. 1, calculation is made by setting the area of the aromatic amide peak at 10.4 ppm at 1.0 and defining the area of the proton peak (symbol 1) of the polymerizable functional groups derived from the terminal structures near 5.7 ppm and 6.1 ppm as the end-capping value. Since peaks of proton peaks of the polymerizable functional groups derived from the repeating structure (two peaks around 5.6 ppm, and two peaks around 6.0 ppm) (symbol 2) are confirmed near the proton peak of the polymerizable functional groups derived from the terminal structure, these proton peaks are excluded from calculation of “end-capping value”.

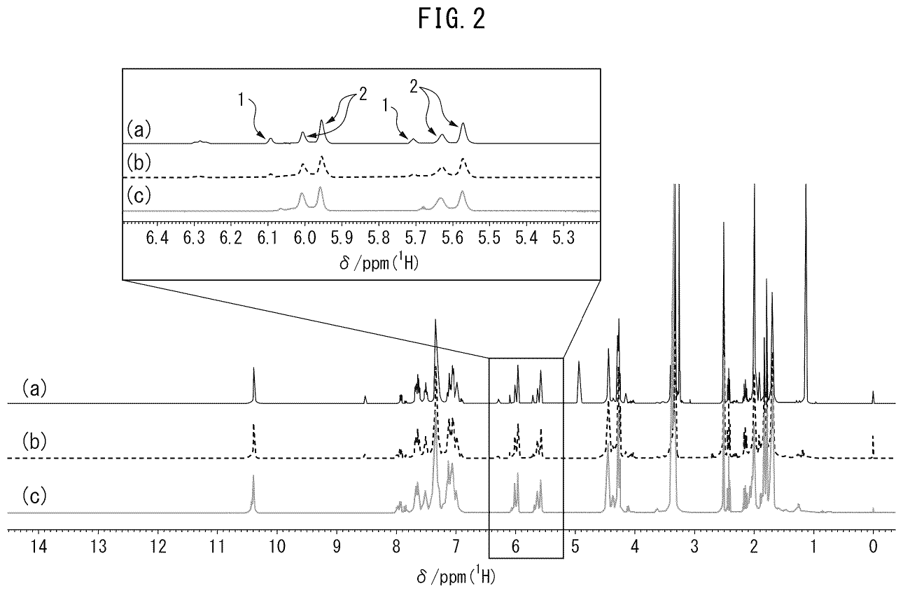

FIG. 2 shows a comparison of ¹H-NMR of a polyimide precursor resin when amine groups derived from a diamine compound located at the end of the main chain is pre-capped, post-capped, and uncapped (unmodified). Also in the case of ¹H-NMR shown in FIG. 2, calculation is made by setting the area of the aromatic amide peak at 10.4 ppm at 1.0 and defining the area of the proton peak (symbol 1) of the polymerizable functional groups derived from the terminal structures near 5.7 ppm and 6.1 ppm as the end-capping value. Since proton peaks of the polymerizable functional groups derived from the repeating structure (two peaks around 5.6 ppm, and two peaks around 6.0 ppm) (symbol 2), and peaks (6.3 ppm) unrelated to the polymerizable functional groups are confirmed near the proton peak of the polymerizable functional groups derived from the terminal structure, these proton peaks are excluded from calculation of “end-capping value”. Comparing the pre-capping and the post-capping, it can be seen that the pre-capping has a higher peak strength than that of the post-capping.

In the photosensitive resin composition of the present disclosure, the polyimide precursor resin (A) includes a terminal structure derived from tetracarboxylic dianhydride at the end of the main chain, and when the peak area of amide groups derived from the main chain structure is set at 1.0 by ¹H-NMR, the end-capping value is preferably 0.02 or more, more preferably 0.04 or more, and still more preferably 0.06 or more. In the photosensitive resin composition of the present disclosure, the polyimide precursor resin (A) includes a terminal structure derived from tetracarboxylic dianhydride at the end of the main chain, and when the peak area of amide groups derived from the main chain structure is set at 1.0 by ¹H-NMR, the end-capping value is preferably 0.06 or more, more preferably 0.07 or more, and still more preferably 0.08 or more. A high capping reaction ratio means a high capping ratio. Due to high capping ratio, the chemical resistance is improved under synthesis conditions with excess acid dianhydride, and, deactivation of reactive active end during polymerization is suppressed under synthesis conditions with excess diamine, and thus the dielectric loss tangent is improved.

### EXAMPLES

Physical properties of the photosensitive resin compositions in Examples (Ex.), Comparative Examples (Comp. Ex.) and Production Examples of the present disclosure were measured and evaluated according to the following methods.

### Measurement and Evaluation Methods

### (1) Weight-Average Molecular Weight

The weight-average molecular weight (Mw) of each photosensitive resin was measured by gel permeation chromatography (in terms of standard polystyrene). The column used for the measurement was Shodex 805M/806M in series manufactured by Showa Denko K.K., and Shodex STANDARD SM-105 manufactured by Showa Denko K.K. was selected as the standard monodisperse polystyrene, and N-methyl-2-pyrrolidone was used as the developing solvent, and Shodex RI-930 manufactured by Showa Denko K.K. was used as the detector.

### (2) Resolution and Developing Time of Cured Relief Pattern on Cu Substrate

Using a sputtering device (Model L-4405-FHL, manufactured by Canon Anelva Corporation), a 200 nm thick Ti layer and a 400 nm thick Cu layer were sputtered in this order on a 6 inch silicon wafer (manufactured by Fujimi Denshi Kogyo Co., Ltd., thickness of 625±25 μm). Subsequently, a photosensitive resin composition prepared by the method described below is spin-coated on this wafer using a coater developer (Model D-Spin60A, manufactured by SOKUDO) and dried by heating on a hot plate at 110° C. for 3 minutes to form a photosensitive resin layer having a thickness of about 13.5 μm. This photosensitive resin layer was irradiated with energy of 300 mJ/cm² from Prisma GHI (manufactured by Ultratech, Inc.) equipped with an i-line filter using a mask with a test pattern. Next, this photosensitive resin layer was spray-developed with a coater developer (Model D-Spin60A, manufactured by SOKUDO) using cyclopentanone as a developing solution, and rinsed with propylene glycol methyl ether acetate to form a relief on Cu. The spray developing time at this time was defined as the developing time. The wafer on which the relief pattern was formed on Cu was heated in a nitrogen atmosphere at 230° C. for 2 hours using a temperature-rising programmable curing furnace (Model VF-2000, manufactured by Koyo Lindberg Ltd.) to obtain a cured relief pattern made of a resin having a thickness of about 10 lam. The relief pattern thus fabricated was observed under an optical microscope to determine the size of a minimum via opening pattern. At this time, if the area of the opening of the obtained pattern is 1/2 or more of the opening area of the corresponding pattern mask, it was regarded as being resolved, and the resolution was judged according to the following evaluation criteria based on the length of the mask opening side corresponding to those having the smallest area of the resolved openings (size of the opening pattern).

### Evaluation Criteria

A: The size of the minimum opening pattern was less than 10 μm;
B: The size of the minimum opening pattern was 10 μm or more and less than 15 μm;
C: The size of the minimum opening pattern was 15 μm or more and less than 20 μm; and
D: The size of the minimum opening pattern was 20 μm or more.

### (3) Chemical Resistance Test

Using a sputtering device (Model L-440S-FHL, manufactured by Canon Anelva Corporation), a 200 nm thick Ti layer and a 400 nm thick Cu layer were sputtered in this order on a 6 inch silicon wafer (manufactured by Fujimi Denshi Kogyo Co., Ltd., thickness of 625±25 μm). Subsequently, a photosensitive resin composition prepared by the method described below is spin-coated on this wafer using a coater developer (Model D-Spin60A, manufactured by SOKUDO) and dried by heating on a hot plate at 110° C. for 3 minutes to form a photosensitive resin layer having a thickness of about 13.5 μm. This photosensitive resin layer was irradiated with energy of 500 mJ/cm² from Prisma GHI (manufactured by Ultratech, Inc.) equipped with an i-line filter using a mask with a test pattern. Next, this photosensitive resin layer was spray-developed with a coater developer (Model D-SPIN636, manufactured by Dainippon Screen Mfg. Co., Ltd., Japan). Then, by rinsing with propylene glycol methyl ether acetate to remove the unexposed area by development, thus obtaining a relief pattern of the polyimide precursor. The wafer with the relief pattern formed thereon was heated in a nitrogen atmosphere at 230° C. for 2 hours using a temperature-rising programmable curing furnace (Model VF-2000, manufactured by Koyo Lindberg Ltd.) to obtain a cured relief pattern made of a resin having a thickness of about 10 μm. The obtained polyimide pattern was immersed in a solution of 1 wt % of potassium hydroxide, 39 wt % of 3-methoxy-3-methyl-1-butanol and 60 wt % of dimethyl sulfoxide at 50° C. for 10 minutes. After washing with water and air drying, the polyimide coating film was evaluated by thickness measurement and observation under an optical microscope. The dissolution rate (DR) per unit minute was calculated from the measured thickness, and the chemical resistance of the coating film after immersion was determined according to the following evaluation criteria.

### Evaluation Criteria

A: The variation in coating film thickness before immersion was within ±3% and cracking did not occur;
B: The variation in coating film thickness was within ±5% before immersion and cracking did not occur;
C: The variation in coating film thickness before immersion was within ±7% and cracking did not occur; and
D: The variation in coating film thickness was more than ±7% before immersion or cracking occurred.

### (4) Measurement of Dielectric Properties (Relative Dielectric Constant: Dk, Dielectric Loss Tangent: Df)

Using a sputtering device (Model L-440S-FHL, manufactured by Canon Anelva Corporation), 100 nm thick aluminum (Al) was sputtered on a 6 inch silicon wafer (manufactured by Fujimi Denshi Kogyo Co., Ltd., thickness 625±25 μm) to prepare a sputtered Al wafer substrate. A photosensitive resin composition prepared by the method described below was spin-coated on the sputtered Al wafer substrate using a spin coater (Model D-Spin60A, manufactured by SOKUDO), and dried by heating at 110° C. for 180 seconds to form a photosensitive resin layer having a thickness of about 13.5 μm. Then, using an aligner (PLA-501F, manufactured by Canon Inc.), the entire surface was exposed to ghi rays at an exposure dose of 600 mJ/cm², followed by a heat-curing treatment at 230° C. for 2 hours under a nitrogen atmosphere using a vertical curing furnace (manufactured by Koyo Lindberg Co., Ltd., model name VF-2000B) to fabricate a cured film made of a resin having a thickness of about 10 μm on an Al wafer. Using a dicing saw (manufactured by Disco Corporation, model name DAD-2H/6T), this cured film was cut into 80 mm long and 62 mm wide (for 10 GHz measurement) and 40 mm long and 30 mm wide (for measurement at 40 GHz), immersed in an aqueous 10% hydrochloric acid and then stripped from the silicon wafer to obtain a film sample. After drying the film sample in an oven at 50° C. for 24 hours, the relative permittivity (Dk) and dielectric loss tangent (DO of the film sample as measured at 10 GHz and 40 GHz by the resonator perturbation method. The details of the measurement method are as follows.

### Measurement Method

Perturbation type split cylinder resonator method

### Equipment Configuration

Network analyzer:

PNA Network analyzer N5224B

(manufactured by Keysight Technologies)

Split cylinder resonator:

CR-710 (manufactured by KANTO ELECTRONIC APPLICATION AND DEVELOPMENT, measurement frequency: about 10 GHz)

CR -740 (manufactured by KANTO ELECTRONIC APPLICATION AND DEVELOPMENT, measurement frequency: about 40 GHz)

### (5) Moisture Permeability Test

Using a sputtering device (Model L-4405-FHL, manufactured by Canon Anelva Corporation), 100 nm thick aluminum (Al) was sputtered on a 6 inch silicon wafer (manufactured by Fujimi Denshi Kogyo Co., Ltd., thickness 625±25 lam) to prepare a sputtered

Al wafer substrate. A photosensitive resin composition prepared by the method described below was spin-coated on the sputtered Al wafer substrate using a spin coater (Model D-Spin60A, manufactured by SOKUDO), and dried by heating at 110° C. for 180 seconds to form a photosensitive resin layer having a thickness of about 13.5 lam. Then, using an aligner (PLA-501F, manufactured by Canon Inc.), the entire surface was exposed to ghi rays at an exposure dose of 600 mJ/cm 2 , followed by a heat-curing treatment at 230° C. for 2 hours under a nitrogen atmosphere using a vertical curing furnace (manufactured by Koyo Lindberg Co., Ltd., model name VF-2000B) to fabricate a cured film made of a resin having a thickness of about 10 lam on an Al wafer. Using a dicing saw (manufactured by Disco Corporation, model name DAD-2H/6T), this cured film was cut into 80 mm long and 62 mm wide, immersed in an aqueous 10% hydrochloric acid and then stripped from the silicon wafer to obtain a film sample. The moisture permeability was measured according to the cup method of JIS Z0208. The amount of calcium chloride used was 40 g, and the test was carried out under moisture permeation conditions of a temperature of 65° C. and a humidity of 90% RH. After 24 hours, the sample was taken out from a thermo-hygrostat and left to stand at room temperature for 30 minutes, followed by the measurement of the weight. The water vapor transmission rate (WVTR) was determined by the following calculation formula:

WVTR={(weight after test)−(weight before test)}/(0.03²×π) (Formula X)

where, in the formula X, 0.03 represents a radius (m) of the cup.

WVTR used herein is the value for a cured film of 10 um and is the value depending on the thickness. For example, when the thickness is 20 μm, the WVTR value is half of that obtained for a thickness of 10 um. The lower the WVTR value, the lower the water vapor transmission rate of the film. The WVTR value tends to decrease as the film becomes more hydrophobic and the density of the film increases.

### Production of Diamine X-1

A 5 L four-necked flask was purged with Ar, and 172.02 g of 4,4′-butylindenebis(6-tert-butyl-m-cresol), 155.84 g of 4-chloronitrobenzene, 1.5 L of DMF were charged therein, followed by stirring. After adding 186.42 g of K₂CO₃ thereto and heating at 150° C. for 5 hours, disappearance of starting materials and intermediates was confirmed by TLC. After cooling to room temperature, the reaction solution was filtered and the filtrate was concentrated under reduced pressure at 80° C. The concentrated residue was poured into 1.6 L of ion-exchanged water and 2.5 L of ethyl acetate was further added, followed by separation and purification three times. The organic layer was collected and dried over MgSO₄. After drying, impurities were removed by filtration and the residue was dissolved by adding 800 mL of toluene, followed by the addition of the solution to 4.0 L of methanol and further stirring for 30 minutes. After stirring, the residue was collected by filtration and dried at 80° C. for 12 hours. The reaction product obtained by drying was charged in a 5 L four-necked flask purged with Ar, and 19.04 g of 5% Pd/C (EA) and 1.9 L of THF were added, followed by stirring. The flask was heated to 40° C. and H₂ bubbling (10 mL/min) was carried out, and then a reduction reaction was carried out for 24 hours. The reaction solution was filtered through celite, and the target fraction was collected by silica gel chromatography and then concentrated under reduced pressure to obtain a diamine X-1.

### (A) Production of Polyimide Precursor

### Synthesis of Polyimide Precursor (Polymer A-1)

In a 1 liter separable flask, 93.7 g of 4,4′-(4,4′-isopropylidenediphenoxy)diphthalic anhydride (BPADA) as an acid component was charged and 175 g of γ-butyrolactone was added. While stirring at room temperature, 4.7 g of a γ-butyrolactone solution prepared by dissolving 4.7 g of 2-isocyanatoethyl methacrylate and 28.9 g of pyridine prepared separately in 20 g of γ-butyrolactone was added over 5 minutes, followed by heating at 50° C. for 1 hour. Then, 48.7 g of 2-hydroxyethyl methacrylate (HEMA) was added and the mixture was further heated at 50° C. for 4 hours, and after completion of heat generation due to the reaction, the reaction solution was allowed to cool to room temperature. The reaction solution was further left to stand for 16 hours to obtain a reaction mixture.

Under ice cooling, a solution obtained by dissolving 69.5 g of dicyclohexylcarbodiimide (DCC) in 70 g of γ-butyrolactone was added to the reaction mixture over 40 minutes while stirring. Subsequently, a solution obtained by dissolving 34.0 g of 2,2′-dimethylbiphenyl-4,4′-diamine (m-TB) as a diamine component in 110 g of γ-butyrolactone was added over 60 minutes while stirring. After further stirring at room temperature for 2.5 hours, 15 g of ethyl alcohol was added, and after stirring for 30 minutes, 150 g of γ-butyrolactone was added. A precipitate formed in the reaction mixture was removed by filtration to obtain a reaction solution.

The obtained reaction solution was added to 2,700 g of ethyl alcohol to form a precipitate composed of a crude polymer. The obtained crude polymer was collected by filtration and dissolved in 1,000 g of γ-butyrolactone to obtain a crude polymer solution. The obtained crude polymer solution was purified with an anion exchange resin (“Amberlyst™ 15” manufactured by ORGANO CORPORATION) to obtain a polymer solution. The obtained polymer solution was added dropwise to 8,000 g of water to precipitate a polymer, and the obtained precipitate was collected by filtration and then vacuum-dried to obtain a powdery polymer A-1. The weight-average molecular weight (Mw) of this polymer A-1 was measured and was found to be 22,000. The end-capping value was 0.04, aliphatic hydrocarbon group concentration T was 8.6 wt %, and photosensitive group concentration S was 27.2 wt %. The “aliphatic hydrocarbon group concentration T” is calculated in terms of the polyimide of the cured polyimide film obtained by heating and curing at 350° C. (the same applies hereinafter).

### Synthesis of Polyimide Precursor (Polymer A-2)

In a 1 liter separable flask, 93.7 g of 4,4′-(4,4′-isopropylidenediphenoxy)diphthalic anhydride (BPADA) as an acid component was charged, and 48.7 g of 2-hydroxyethyl methacrylate (HEMA) and 175 g of γ-butyrolactone were added. While stirring at room temperature, 28.5 g of pyridine was added and the mixture was further heated at 50° C. for 4 hours, and after completion of heat generation due to the reaction, the reaction solution was allowed to cool to room temperature. The reaction solution was further left to stand for 16 hours to obtain a reaction mixture. Then, 4.7 g of 2-isocyanatoethyl methacrylate and 0.4 g of pyridine were dissolved in 20 g of γ-butyrolactone and the γ-butyrolactone solution was added over 5 minutes while stirring and the mixture was further heated at 50° C. for 7 hours, and after completion of heat generation due to the reaction, the reaction solution was allowed to cool to room temperature. The reaction solution was further left to stand for 16 hours to obtain a reaction mixture.

Under ice cooling, a solution obtained by dissolving 73.2 g of dicyclohexylcarbodiimide (DCC) in 70 g of γ-butyrolactone was added to the reaction mixture over 40 minutes while stirring. Subsequently, a solution obtained by dissolving 34.0 g of 2,2′-dimethylbiphenyl-4,4′-diamine (m-TB) as a diamine component in 110 g of γ-butyrolactone was added over 60 minutes while stirring. After further stirring at room temperature for 2.5 hours, 15 g of ethyl alcohol was added, and after stirring for 30 minutes, 150 g of γ-butyrolactone was added. A precipitate formed in the reaction mixture was removed by filtration to obtain a reaction solution.

The obtained reaction solution was added to 2,700 g of ethyl alcohol to form a precipitate composed of a crude polymer. The obtained crude polymer was collected by filtration and dissolved in 1,000 g of γ-butyrolactone to obtain a crude polymer solution. The obtained crude polymer solution was purified with an anion exchange resin (“Amberlyst™ 15” manufactured by ORGANO CORPORATION) to obtain a polymer solution. The obtained polymer solution was added dropwise to 8,000 g of water to precipitate a polymer, and the obtained precipitate was collected by filtration and then vacuum-dried to obtain a powdery polymer A-2. The weight-average molecular weight (Mw) of this polymer A-2 was measured and was found to be 15,000. The end-capping value was 0.02, aliphatic hydrocarbon group concentration T was 8.6 wt %, and photosensitive group concentration S was 27.2 wt %.

### Synthesis of Polyimide Precursor (Polymer A-3)

In a 1 liter separable flask, 93.7 g of 4,4′-(4,4′-isopropylidenediphenoxy)diphthalic anhydride (BPADA) as an acid component was charged, and 48.7 g of 2-hydroxyethyl methacrylate (HEMA) and 175 g of γ-butyrolactone were added. While stirring at room temperature, 28.5 g of pyridine was added and the mixture was further heated at 50° C. for 4 hours, and after completion of heat generation due to the reaction, the reaction solution was allowed to cool to room temperature. The reaction solution was further left to stand for 16 hours to obtain a reaction mixture.

In a separately prepared 0.5 liter three-necked flask, 41.7 g of 2,2′-dimethylbiphenyl-4,4′-diamine (m-TB) as a diamine component was charged and then dissolved by adding 125 g of γ-butyrolactone, and while stirring the resulting solution under ice cooling, 4.7 g of 2-isocyanatoethyl methacrylate was dissolved in 20 g of γ-butyrolactone, and the separately prepared γ-butyrolactone solution was added in the three-necked flask over 5 minutes, followed by stirring for 1 hour under ice cooling to obtain a reaction mixture solution with diamine.

In parallel with the reaction in the 0.5 liter three-necked flask, a solution obtained by dissolving 73.2 g of dicyclohexylcarbodiimide (DCC) in 70 g of γ-butyrolactone was added to the reaction mixture in the 1 liter separable flask under ice cooling was added over 40 minutes with stirring. Subsequently, the reaction mixture solution with the diamine obtained above as the diamine component was added over 60 minutes while stirring. After further stirring at room temperature for 2.5 hours, 150 g of γ-butyrolactone was added. A precipitate formed in the reaction mixture was removed by filtration to obtain a reaction solution.

The obtained reaction solution was added to 2,700 g of ethyl alcohol to form a precipitate composed of a crude polymer. The obtained crude polymer was collected by filtration and dissolved in 1,000 g of y-butyrolactone to obtain a crude polymer solution. The obtained crude polymer solution was purified with an anion exchange resin (“Amberlyst™ 15” manufactured by ORGANO CORPORATION) to obtain a polymer solution. The obtained polymer solution was added dropwise to 8,000 g of water to precipitate a polymer, and the obtained precipitate was collected by filtration and then vacuum-dried to obtain a powdery polymer A-3. The weight-average molecular weight (Mw) of this polymer A-3 was measured and was found to be 17,000. The end-capping value was 0.09, aliphatic hydrocarbon group concentration T was 8.6 wt %, and photosensitive group concentration S was 27.2 wt %.

### Synthesis of Polyimide Precursor (Polymer A-4)

The reaction was carried out in the same manner as in the method described in Synthesis of Polymer A-1, except that 55.8 g of 4,4′-oxydiphthalic dianhydride (ODPA) was used in place of 93.7 g of BPADA, and 65.7 g of 2,2-bis[4-(4-aminophenoxy)phenyl]propane (BAPP) was used in place of 34.0 g of m-TB in Synthesis of Polymer A-1, a polymer A-4 was obtained. The weight-average molecular weight (Mw) of this polymer A-4 was measured and was found to be 21,000. The end-capping value was 0.07, aliphatic hydrocarbon group concentration T was 4.4 wt %, and photosensitive group concentration S was 27.5 wt %.

### Synthesis of Polyimide Precursor (Polymer A-5)

The reaction was carried out in the same manner as in the method described in Synthesis of Polymer A-1, except that 55.8 g of ODPA was used in place of 93.7 g of BPADA, and 70.2 g of 2,2-bis[4-(4-aminophenoxy)phenyl]propane (BAPP) was used in place of 34.0 g of m-TB in Synthesis of Polymer A-1, a polymer A-5 was obtained. The weight-average molecular weight (Mw) of this polymer A-5 was measured and was found to be 20,000. The end-capping value was 0.07, aliphatic hydrocarbon group concentration T was 8.4 wt %, and photosensitive group concentration S was 26.7 wt %.

### Synthesis of Polyimide Precursor (Polymer A-6)

The reaction was carried out in the same manner as in the method described in Synthesis of Polymer A-1, except that 53.0 g of 3,3′,4,4′-biphenyltetracarboxylic dianhydride (BPDA) was used in place of 93.7 g of BPADA, and 70.2 g of MBAPP was used in place of 34.0 g of m-TB in Synthesis of Polymer A-1, a polymer A-6 was obtained. The weight-average molecular weight (Mw) of this polymer A-6 was measured and was found to be 20,000. The end-capping value was 0.06, aliphatic hydrocarbon group concentration T was 8.6 wt %, and photosensitive group concentration S was 27.2 wt %.

### Synthesis of Polyimide Precursor (Polymer A-7)

The reaction was carried out in the same manner as in the method described in Synthesis of Polymer A-1, except that 70.2 g of MBAPP was used in place of 34.0 g of m-TB in Synthesis of Polymer A-1, a polymer A-7 was obtained. The weight-average molecular weight (Mw) of this polymer A-7 was measured and was found to be 23,000. The end-capping value was 0.04, aliphatic hydrocarbon group concentration T was 9.8 wt %, and photosensitive group concentration S was 22 wt %.

### Synthesis of Polyimide Precursor (Polymer A-8)

The reaction was carried out in the same manner as in the method described in Synthesis of Polymer A-1, except that 53.0 g of BPDA was used in place of 93.7 g of BPADA, and 64.7 g of 1,4-bis(4-aminophenoxy)-2,5-di-t-butylbenzene (DTBAB) was used in place of 34.0 g of m-TB in Synthesis of Polymer A-1, a polymer A-8 was obtained. The weight-average molecular weight (Mw) of this polymer A-8 was measured and was found to be 21,000. The end-capping value was 0.06, aliphatic hydrocarbon group concentration T was 16.2 wt %, and photosensitive group concentration S was 22.6 wt %.

### Synthesis of Polyimide Precursor (Polymer A-9)

The reaction was carried out in the same manner as in the method described in Synthesis of Polymer A-1, except that 90.4 g of a diamine X-1 was used in place of 34.0 g of m-TB in Synthesis of Polymer A-1, a polymer A-9 was obtained. The weight-average molecular weight (Mw) of this polymer A-9 was measured and was found to be 19,000. The end-capping value was 0.04, aliphatic hydrocarbon group concentration T was 20.7 wt %, and photosensitive group concentration S was 19.9 wt %.

### Synthesis of Polyimide Precursor (Polymer A-10)

The reaction was carried out in the same manner as in the method described in Synthesis of Polymer A-1, except that 39.3 g of pyromellitic dianhydride (PD) was used in place of 93.7 g of BPADA, and 90.4 g of a diamine X-1 was used in place of 34.0 g of m-TB in Synthesis of Polymer A-1, a polymer A-10 was obtained. The weight-average molecular weight (Mw) of this polymer A-10 was measured and was found to be 13,000. The end-capping value was 0.1, aliphatic hydrocarbon group concentration T was 25.1 wt %, and photosensitive group concentration S was 25.8 wt %.

### Synthesis of Polyimide Precursor (Polymer A-11)

The reaction was carried out in the same manner as in the method described in Synthesis of Polymer A-1, except that 55.8 g of ODPA was used in place of 93.7 g of BPADA, and 35.1 g of MBAPP and 16.0 g of diaminophenyl ether (DADPE) were used in place of 34.0 g of m-TB in Synthesis of Polymer A-1, a polymer A-11 was obtained. The weight-average molecular weight (Mw) of this polymer A-11 was measured and was found to be 19,000. The end-capping value was 0.07, aliphatic hydrocarbon group concentration T was 5.1 wt %, and photosensitive group concentration S was 30.5 wt %.

### Synthesis of Polyimide Precursor (Polymer A-12)

The reaction was carried out in the same manner as in the method described in Synthesis of Polymer A-1, except that 55.8 g of ODPA was used in place of 93.7 g of BPADA, and 90.4 g of a diamine X-1 was used in place of 34.0 g of m-TB in Synthesis of Polymer A-1, a polymer A-12 was obtained. The weight-average molecular weight (Mw) of this polymer A-12 was measured and was found to be 15,000. The end-capping value was 0.07, aliphatic hydrocarbon group concentration T was 22.3 wt %, and photosensitive group concentration S was 23.7 wt %.

### Synthesis of Polyimide Precursor (Polymer A-13)

The reaction was carried out in the same manner as in the method described in Synthesis of Polymer A-1, except that 39.3 g of PD was used in place of 93.7 g of BPADA, and 70.2 g of MBAPP was used in place of 34.0 g of m-TB in Synthesis of Polymer A-1, a polymer A-13 was obtained. The weight-average molecular weight (Mw) of this polymer A-13 was measured and was found to be 18,000. The end-capping value was 0.1, aliphatic hydrocarbon group concentration T was 9.7 wt %, and photosensitive group concentration S was 29.5 wt %.

### Synthesis of Polyimide Precursor (Polymer A-14)

The reaction was carried out in the same manner as in the method described in Synthesis of Polymer A-1, except that 59.2 g of hydroxybutyl methacrylate (HBMA) was used in place of 48.7 g of HEMA in Synthesis of Polymer A-1, a polymer A-14 was obtained. The weight-average molecular weight (Mw) of this polymer A-14 was measured and was found to be 23,000. The end-capping value was 0.04, aliphatic hydrocarbon group concentration T was 8.6 wt %, and photosensitive group concentration S was 31.2 wt %.

### Synthesis of Polyimide Precursor (Polymer A-15)

The reaction was carried out in the same manner as in the method described in Synthesis of Polymer A-1, except that 4.1 g of 2-isocyanatoethyl methacrylate and 0.9 g of 1,1-(bisacryloyloxymethyl)ethyl isocyanate were used in place of 4.7 g of 2-isocyanatoethyl methacrylate in Synthesis of Polymer A-1, a polymer A-15 was obtained. The weight-average molecular weight (Mw) of this polymer A-15 was measured and was found to be 18,000. The end-capping value was 0.04, aliphatic hydrocarbon group concentration T was 8.6 wt %, and photosensitive group concentration S was 27.2 wt %.

### Synthesis of Polyimide Precursor (polymer A-16)

In a 1 liter separable flask, 93.7 g of 4,4′-(4,4′-isopropylidenediphenoxy)diphthalic anhydride (BPADA) as an acid component was charged, and 48.7 g of 2-hydroxyethyl methacrylate (HEMA) and 175 g of γ-butyrolactone were added. While stirring at room temperature, 28.5g of pyridine was added and the mixture was further heated at 50° C. for 4 hours, and after completion of heat generation due to the reaction, the reaction solution was allowed to cool to room temperature. The reaction solution was further left to stand for 16 hours to obtain a reaction mixture.

Under ice cooling, a solution obtained by dissolving 73.2 g of dicyclohexylcarbodiimide (DCC) in 70 g of γ-butyrolactone was added to the reaction mixture over 40 minutes while stirring. Subsequently, 1.4 g of allylamine was dissolved in 20 g of γ-butyrolactone, and the γ-butyrolactone solution was added over 5 minutes while stirring, and then a solution obtained by dissolving 35.7 g of 2,2′-dimethylbiphenyl-4,4′-diamine (m-TB) as a diamine component in 110 g of γ-butyrolactone was added over 60 minutes while stirring. After further stirring at room temperature for 2.5 hours, 15 g of ethyl alcohol was added, and after stirring for 30 minutes, 150 g of γ-butyrolactone was added and 0.05 g of 4-methoxyphenol was further added, followed by stirring at 50° C. for 0.5 hour. A precipitate formed in the reaction mixture was removed by filtration to obtain a reaction solution.

The obtained reaction solution was added to 2,700 g of ethyl alcohol to form a precipitate composed of a crude polymer. The obtained crude polymer was collected by filtration and dissolved in 1,000 g of y-butyrolactone to obtain a crude polymer solution. The obtained crude polymer solution was purified with an anion exchange resin (“Amberlyst™ 15” manufactured by ORGANO CORPORATION) to obtain a polymer solution. The obtained polymer solution was added dropwise to 8,000 g of water to precipitate a polymer, and the obtained precipitate was collected by filtration and then vacuum-dried to obtain a powdery polymer A-16. The weight-average molecular weight (Mw) of this polymer A-16 was measured and was found to be 16,000. The end-capping value was 0.08, aliphatic hydrocarbon group concentration T was 8.6 wt %, and photosensitive group concentration S was 27.2 wt %.

### Synthesis of Polyimide Precursor (Polymer A-17)

The reaction was carried out in the same manner as in the method described in Synthesis of Polymer A-3, except that 55.8 g of ODPA was used in place of 93.7 g of BPADA, 84.6 g of 2,2-bis[4-(4-aminophenoxy)-3-methylphenyl]propane (MBAPP) was used in place of 34.0 g of m-TB, and 3.2 g of 2-isocyanatoethyl methacrylate and 0.7 g of 1,1-(bisacryloyloxymethyl)ethyl isocyanate were used in place of 4.7 g of 2-isocyanatoethyl methacrylate in Synthesis of Polymer A-3, a polymer A-17 was obtained. The weight-average molecular weight (Mw) of this polymer A-17 was measured and was found to be 21,000. The end-capping value was 0.07, aliphatic hydrocarbon group concentration T was 8.4 wt %, and photosensitive group concentration S was 27.5 wt %.

### Synthesis of Polyimide Precursor (Polymer A-18)

The reaction was carried out in the same manner as in the method described in Synthesis of Polymer A-3, except that 34.0 g of m-TB was changed to 40.9 g, and 2.5 g of methacrylic acid chloride was used in place of 4.7 g of 2-isocyanatoethyl methacrylate in Synthesis of Polymer A-3, a polymer A-18 was obtained. The weight-average molecular weight (Mw) of this polymer A-18 was measured and was found to be 17,000. The end-capping value was 0.06, aliphatic hydrocarbon group concentration T was 8.6 wt %, and photosensitive group concentration S was 27.2 wt %.

### Synthesis of Polyimide Precursor (Polymer A-19)

The reaction was carried out in the same manner as in the method described in Synthesis of Polymer A-16, except that 2.95 g of 5-norbornene-2-methylamine was used in place of 1.4 g of allylamine in Synthesis of Polymer A-16, a polymer A-19 was obtained. The weight-average molecular weight (Mw) of this polymer A-19 was measured and was found to be 16,000. The end-capping value was 0.08, aliphatic hydrocarbon group concentration T was 8.6 wt %, and photosensitive group concentration S was 27.2 wt %.

### Synthesis of Polyimide Precursor (Polymer A-20)

In a 1 liter separable flask, 55.8 g of ODPA as an acid component was charged, and 48.7 g of HEMA and 175 g of y-butyrolactone were added. While stirring at room temperature, 28.5 g of pyridine was added to obtain a reaction mixture. After completion of heat generation due to the reaction, the reaction solution was allowed to cool to room temperature and then further left to stand for 16 hours.

Under ice cooling, a solution obtained by dissolving 69.5 g of dicyclohexylcarbodiimide (DCC) in 70 g of γ-butyrolactone was added to the reaction mixture over 40 minutes while stirring, and then a suspension obtained by suspending 30.9 g of DADPE as a diamine component in 100 g of γ-butyrolactone was added over 60 minutes while stirring. After further stirring at room temperature for 2.5 hours, 15 g of ethyl alcohol was added, and after stirring for 30 minutes, 150 g of γ-butyrolactone was added. A precipitate formed in the reaction mixture was removed by filtration to obtain a reaction solution.

The obtained reaction solution was added to 2,700 g of ethyl alcohol to form a precipitate composed of a crude polymer. The obtained crude polymer was collected by filtration and dissolved in 1,000 g of γ-butyrolactone to obtain a crude polymer solution. The obtained crude polymer solution was purified with an anion exchange resin (“Amberlyst™ 15” manufactured by ORGANO CORPORATION) to obtain a polymer solution. The obtained polymer solution was added dropwise to 8,000 g of water to precipitate a polymer, and the obtained precipitate was collected by filtration and then vacuum-dried to obtain a powdery polymer A-20. The weight-average molecular weight (Mw) of this polymer A-20 was measured and was found to be 22,000. Aliphatic hydrocarbon group concentration T was 0 wt %, and photosensitive group concentration S was 35.4 wt %.

### Synthesis of Polyimide Precursor (Polymer A-21)

In a 2 liter separable flask, 155.1 g of ODPA as an acid component was charged, and 134.0 g of 2-hydroxyethyl methacrylate (HEMA) and 400 ml of γ-butyrolactone were added. While stirring at room temperature, 79.1 g of pyridine was added to obtain a reaction mixture. After completion of heat generation due to the reaction, the reaction solution was allowed to cool to room temperature and then further left to stand for 16 hours.

Under ice cooling, a solution obtained by dissolving 206.3 g of dicyclohexylcarbodiimide (DCC) in 180 ml of γ-butyrolactone was added to the reaction mixture over 40 minutes while stirring. Subsequently, a suspension obtained by suspending 120.1 g of 4,4′-diaminodiphenyl ether (DADPE) as a diamine component in 360 ml of γ-butyrolactone was added over 60 minutes while stirring. After further stirring at room temperature for 2 hours, 37.2 g of 2-isocyanatoethyl methacrylate as a terminal modifier at the diamine end was added, followed by stirring for 2 hours. Thereafter, 400 ml of y-butyrolactone was added. A precipitate formed in the reaction mixture was removed by filtration to obtain a reaction solution.

The obtained reaction solution was added to 3 liters of ethyl alcohol to form a precipitate composed of a crude polymer. The obtained crude polymer was collected by filtration and dissolved in 1.5 liters of tetrahydrofuran to obtain a crude polymer solution. The obtained crude polymer solution was added dropwise to 28 liters of water to precipitate a polymer, and the obtained precipitate was collected by filtration and then vacuum-dried to obtain a powdery polymer A-21. The weight-average molecular weight (Mw) of this polymer A-21 was measured and was found to be 20,000. The end-capping value was 0.05, aliphatic hydrocarbon group concentration T was 0 wt %, and photosensitive group concentration S was 35.4 wt %.

### Synthesis of Polyimide Precursor (Polymer A-22)

The reaction was carried out in the same manner as in the method described in Synthesis of Polymer A-20, except that 56.8 g of BAPB was used in place of 30.9 g of DADPE in Synthesis of Polymer A-20, a polymer A-22 was obtained. The weight-average molecular weight (Mw) of this polymer A-22 was measured and was found to be 23,000. Aliphatic hydrocarbon group concentration T was 0 wt %, and photosensitive group concentration S was 28.8 wt %.

### Synthesis of Polyimide Precursor (Polymer A-23)

The reaction was carried out in the same manner as in the method described in Synthesis of Polymer A-20, except that 32.8 g of m-TB was used in place of 30.9 g of DADPE in Synthesis of Polymer A-20, a polymer A-23 was obtained. The weight-average molecular weight (Mw) of this polymer A-23 was measured and was found to be 19,000. Aliphatic hydrocarbon group concentration T was 6.2 wt %, and photosensitive group concentration S was 34.9 wt %.

### Synthesis of Polyimide Precursor (Polymer A-24)

The reaction was carried out in the same manner as in the method described in Synthesis of Polymer A-21, except that 127.37 g of m-TB was used in place of 120.14 g of DADPE in Synthesis of Polymer A-21, a polymer A-24 was obtained. The weight-average molecular weight (Mw) of this polymer A-24 was measured and was found to be 21,000. The end-capping value was 0.05, aliphatic hydrocarbon group concentration T was 6.2 wt %, and photosensitive group concentration S was 34.9 wt %.

### Synthesis of Polyimide Precursor (Polymer A-25)

The reaction was carried out in the same manner as in the method described in Synthesis of Polymer A-21, except that 91.0 g of m-TB was used in place of 120.1 g of DADPE, and 24.5 g of 4-vinylaniline was used in place of 37.2 g of 2-isocyanatoethyl methacrylate in Synthesis of Polymer A-21, a polymer A-25 was obtained. The weight-average molecular weight (Mw) of this polymer A-25 was measured and was found to be 20,000. The end-capping value was 0.01, aliphatic hydrocarbon group concentration T was 6.2 wt %, and photosensitive group concentration S was 34.9 wt %.

### Components (B) to (G)

Photopolymerization initiator B1: 3-Cyclopentyl-1-[9-ethyl-6-(2-methylbenzoyl)-9H-carbazol-3-yl]propanone-1-(O-acetyl oxime) (trade name: PBG-304, manufactured by Changzhou Tronly New Electronic Materials Co., Ltd.)

Photopolymerization initiator B2: 1,2-Propanedione-3-cyclopentyl-1-[4-(phenylthio)phenyl]-2-(O-benzoyl oxime) (trade name: PBG-305, manufactured by Changzhou Tronly New Electronic Materials Co., Ltd.)

Photopolymerization initiator B3: 1-[4-(phenylthio)phenyl]-3-propane-1,2-dione-2-(O-acetyl oxime) (trade name: PBG-3057, manufactured by Changzhou Tronly New Electronic Materials Co., Ltd.)

Solvent C1: γ-Butyrolactone

Solvent C2: Dimethyl sulfoxide (DMSO)

Silane coupling agent D-1: 3-Glycidoxypropyltrimethoxysilane (Shin-Etsu Chemical Co., Ltd.)

Silane coupling agent D-2: N-phenyl-3-aminopropyltrimethoxysilane (manufactured by Shin-Etsu Chemical Co., Ltd.)

Silane coupling agent D-3: (3-Triethoxysilylpropyl)-tert-butylcarbamate

Silane Coupling agent D-4: Ureidopropyltriethoxysilane (manufactured by Shin-Etsu Chemical Co., Ltd.)

Silane coupling agent D-5: X-12-1214A (trade name, manufactured by Shin-Etsu Chemical Co., Ltd.)

Silane coupling agent D-6: Tris(-trimethoxysilylpropyl) isocyanurate (manufactured by Shin-Etsu Chemical Co., Ltd.)

Radically polymerizable compound E-1: 1,9-Nonanediol dimethacrylate (manufactured by Shin-Nakamura Chemical Co., Ltd.)

Radically polymerizable compound E-2: 1,6-Hexanediol dimethacrylate (manufactured by Shin-Nakamura Chemical Co., Ltd.)

Radical polymerizable compound E-3: Diacrylate of polyoxypropylene bisphenol A (manufactured by Kyoeisha Chemical Co., Ltd.)

Thermal crosslinking agent F-1: BMI-5100 (manufactured by Daiwa Kasei Industry Co., Ltd.)

Thermal crosslinking agent F-2: SBB70P (manufactured by Asahi Kasei Corporation)

Filler G-1: K180SP-CY1 (manufactured by Admatechs)

### Examples and Comparative Examples

### Example 1

As shown in Table 1, 100 g of a polymer A-1 as a component (A) and 5 g of a photopolymerization initiator B-1 as a component (B) were dissolved in a mixed solvent of γ-butyrolactone and DMSO (weight ratio of 90:10) as a solvent (C), and then the amount of the solvent was adjusted so as to have a viscosity of 40 poise to obtain a photosensitive resin composition solution. This composition was evaluated by the method described above. The characteristics and evaluation results are shown in Table 2. The characteristics of the component (A) are shown in Table 9.

### Examples 3 to 39, Comparative Examples 1 to 6

In the same manner as in Example 1, except that the types and amounts of the components were adjusted to the proportions shown in Tables 1, 3, 5 and 7, photosensitive resin compositions were prepared and then evaluated. The characteristics and evaluation results are shown in Tables 2, 4, 6 and 8. The characteristics of the component (A) are shown in Table 9.

TABLE 1

| | | Ex. 1 | Ex. 2 | Ex. 3 | Ex. 4 | Ex. 5 | Ex. 6 | Ex. 7 | Ex. 8 | Ex. 9 | Ex. 10 | Ex. 11 |
|---|---|---|---|---|---|---|---|---|---|---|---|---|
| (A) Polyimide precursor | A-1 | 100 | | | 100 | 100 | | | | | | |
| (g) | A-2 | | 100 | | | | 100 | | | | | |
| | A-3 | | | 100 | | | | 100 | | | | |
| | A-4 | | | | | | | | 100 | | | |
| | A-5 | | | | | | | | | 100 | | |
| | A-6 | | | | | | | | | | 100 | |
| | A-7 | | | | | | | | | | | 100 |
| | A-8 | | | | | | | | | | | |
| | A-9 | | | | | | | | | | | |
| | A-10 | | | | | | | | | | | |
| | A-11 | | | | | | | | | | | |
| | A-12 | | | | | | | | | | | |
| | A-13 | | | | | | | | | | | |
| | A-14 | | | | | | | | | | | |
| | A-15 | | | | | | | | | | | |
| | A-16 | | | | | | | | | | | |
| | A-17 | | | | | | | | | | | |
| | A-18 | | | | | | | | | | | |
| | A-19 | | | | | | | | | | | |
| | A-20 | | | | | | | | | | | |
| | A-21 | | | | | | | | | | | |
| | A-22 | | | | | | | | | | | |
| | A-23 | | | | | | | | | | | |
| | A-24 | | | | | | | | | | | |
| | A-25 | | | | | | | | | | | |
| (B) Photopolymerization | B-1 | 5 | 5 | | 5 | 5 | 5 | | 5 | 5 | 5 | 5 |
| initiator (g) | B-2 | | | | | | | | | | | |
| | B-3 | | | 5 | | | | 5 | | | | |
| (C) Solvent (g) | C-1 | 180 | 180 | 180 | 180 | 180 | 180 | 180 | 180 | 180 | 180 | 180 |
| | C-2 | 20 | 20 | 20 | 20 | 20 | 20 | 20 | 20 | 20 | 20 | 20 |
| (D) Adhesion aid (g) | D-1 | | | | 2 | 2 | 2 | 2 | 2 | 2 | 2 | 2 |
| | D-2 | | | | | | | | | | | |
| | D-3 | | | | | | | | | | | |
| | D-4 | | | | | | | | | | | |
| | D-5 | | | | | | | | | | | |
| | D-6 | | | | | | | | | | | |
| (E) Radically | E-1 | | | | | 10 | 10 | 10 | 10 | 10 | 10 | 10 |
| polymerizable compound | E-2 | | | | | | | | | | | |
| (g) | E-3 | | | | | | | | | | | |
| (F) Thermal crosslinking | F-1 | | | | | | | | | | | |
| agent (g) | F-2 | | | | | | | | | | | |
| (G) Filler (g) | G-1 | | | | | | | | | | | |

TABLE 2

| | Ex. 1 | Ex. 2 | Ex. 3 | Ex. 4 | Ex. 5 | Ex. 6 | Ex. 7 | Ex. 8 | Ex. 9 | Ex. 10 | Ex. 11 |
|---|---|---|---|---|---|---|---|---|---|---|---|
| Resolution | B | A | A | B | A | A | A | B | A | A | B |
| Developing | 40 | 25 | 32 | 40 | 25 | 20 | 22 | 20 | 15 | 23 | 9 |
| time (s) | | | | | | | | | | | |
| Chemical | B | B | B | B | A | A | A | A | A | A | C |
| resistance | | | | | | | | | | | |
| Dissolution | 4.44 | 4.81 | 4.07 | 3.85 | 2.37 | 2.89 | 2.22 | 2.96 | 2.96 | 2.96 | 5.93 |
| rate: DR | | | | | | | | | | | |
| (nm/min) | | | | | | | | | | | |
| Dk (10 GHz) | 2.9 | 2.9 | 2.9 | 2.9 | 2.9 | 2.9 | 2.9 | 3.1 | 2.9 | 3.1 | 2.9 |
| Df (10 GHz) | 0.0057 | 0.0058 | 0.0054 | 0.0053 | 0.0060 | 0.0060 | 0.0058 | 0.0109 | 0.0060 | 0.0061 | 0.0055 |
| Dk (40 GHz) | 2.9 | 2.9 | 2.9 | 2.9 | 2.9 | 2.9 | 2.9 | 3.0 | 2.9 | 3.1 | 2.9 |
| Df (40 GHz) | 0.0067 | 0.0067 | 0.0064 | 0.0063 | 0.0070 | 0.0070 | 0.0067 | 0.0124 | 0.007 | 0.0071 | 0.0065 |
| Moisture | 583 | 592 | 572 | 583 | 669 | 669 | 652 | 776 | 587 | 551 | 541 |
| permeability: | | | | | | | | | | | |
| WVTR | | | | | | | | | | | |
| Tanδ40 × | 3.89 | 3.97 | 3.66 | 3.69 | 4.70 | 4.70 | 4.37 | 9.58 | 4.13 | 3.93 | 3.49 |
| WVTR | | | | | | | | | | | |
| Tanδ40 × | 17.31 | 19.10 | 14.91 | 14.21 | 11.14 | 13.58 | 9.71 | 28.40 | 12.22 | 11.63 | 20.71 |
| WVTR × DR | | | | | | | | | | | |
| 4 T − 3 S | −47.20 | −47.20 | −47.20 | −47.20 | −47.20 | −47.20 | −47.20 | −64.90 | −46.50 | −47.20 | −26.80 |

TABLE 3

| | | Ex. 12 | Ex. 13 | Ex. 14 | Ex. 15 | Ex. 16 | Ex. 17 | Ex. 18 | Ex. 19 | Ex. 20 | Ex. 21 | Ex. 22 |
|---|---|---|---|---|---|---|---|---|---|---|---|---|
| (A) Polyimide precursor | A-1 | | | | | | | | | | | |
| (g) | A-2 | | | | | | | | | | | |
| | A-3 | | | | | | | | | | | |
| | A-4 | | | | | | | | | | | |
| | A-5 | | | | | | | | | | | |
| | A-6 | | | | | | | | | | | |
| | A-7 | | | | | | | | | | | |
| | A-8 | 100 | | | | | | | | | | |
| | A-9 | | 100 | | | | | | | | | |
| | A-10 | | | 100 | | | | | | | | |
| | A-11 | | | | 100 | | | | | | | |
| | A-12 | | | | | 100 | | | | | | |
| | A-13 | | | | | | 100 | | | | | |
| | A-14 | | | | | | | 100 | | | | |
| | A-15 | | | | | | | | 100 | | | |
| | A-16 | | | | | | | | | 100 | | |
| | A-17 | | | | | | | | | | 100 | |
| | A-18 | | | | | | | | | | | 100 |
| | A-19 | | | | | | | | | | | |
| | A-20 | | | | | | | | | | | |
| | A-21 | | | | | | | | | | | |
| | A-22 | | | | | | | | | | | |
| | A-23 | | | | | | | | | | | |
| | A-24 | | | | | | | | | | | |
| | A-25 | | | | | | | | | | | |
| (B) Photopolymerization | B-1 | 5 | 5 | 5 | 5 | 5 | 5 | 5 | 5 | | | |
| initiator (g) | B-2 | | | | | | | | | | | |
| | B-3 | | | | | | | | | 5 | 5 | 5 |
| (C) Solvent (g) | C-1 | 180 | 180 | 180 | 180 | 180 | 180 | 180 | 180 | 180 | 180 | 180 |
| | C-2 | 20 | 20 | 20 | 20 | 20 | 20 | 20 | 20 | 20 | 20 | 20 |
| (D) Adhesion aid (g) | D-1 | 2 | 2 | 2 | 2 | 2 | 2 | 2 | 2 | 2 | 2 | 2 |
| | D-2 | | | | | | | | | | | |
| | D-3 | | | | | | | | | | | |
| | D-4 | | | | | | | | | | | |
| | D-5 | | | | | | | | | | | |
| | D-6 | | | | | | | | | | | |
| (E) Radically | E-1 | 10 | 10 | 10 | 10 | 10 | 10 | 10 | 10 | 10 | 10 | 10 |
| polymerizable | E-2 | | | | | | | | | | | |
| compound (g) | E-3 | | | | | | | | | | | |
| (F) Thermal crosslinking | F-1 | | | | | | | | | | | |
| agent (g) | F-2 | | | | | | | | | | | |
| (G) Filler (g) | G-1 | | | | | | | | | | | |

TABLE 4

| | Ex. 12 | Ex. 13 | Ex. 14 | Ex. 15 | Ex. 16 | Ex. 17 | Ex. 18 | Ex. 19 | Ex. 20 | Ex. 21 | Ex. 22 |
|---|---|---|---|---|---|---|---|---|---|---|---|
| Resolution | B | C | A | A | B | A | A | A | A | A | A |
| Developing | 16 | 9 | 14 | 30 | 10 | 18 | 22 | 25 | 20 | 16 | 22 |
| time (s) | | | | | | | | | | | |
| Chemical | B | C | A | A | B | A | A | A | B | A | A |
| resistance | | | | | | | | | | | |
| Dissolution | 4.81 | 6.30 | 2.96 | 2.81 | 4.81 | 2.67 | 2.81 | 1.85 | 4.44 | 2.44 | 2.59 |
| rate: DR | | | | | | | | | | | |
| (nm/min) | | | | | | | | | | | |
| Dk (10 GHz) | 2.9 | 2.9 | 3.1 | 3.0 | 3.0 | 3.0 | 3.0 | 2.9 | 2.9 | 2.9 | 2.9 |
| Df (10 GHz) | 0.0071 | 0.0058 | 0.0085 | 0.0104 | 0.0080 | 0.0070 | 0.0064 | 0.0061 | 0.0063 | 0.0059 | 0.0058 |
| Dk (40 GHz) | 2.9 | 2.9 | 3.1 | 3.0 | 3.0 | 3.0 | 3.0 | 3.0 | 2.9 | 2.9 | 2.9 |
| Df (40 GHz) | 0.0081 | 0.0068 | 0.0095 | 0.011 | 0.0090 | 0.0080 | 0.0074 | 0.0071 | 0.0073 | 0.0069 | 0.0067 |
| Moisture | 503 | 549 | 621 | 675 | 585 | 674 | 702 | 655 | 672 | 572 | 650 |
| permeability: | | | | | | | | | | | |
| WVTR | | | | | | | | | | | |
| Tanδ40 × | 4.06 | 3.76 | 5.90 | 7.70 | 5.28 | 5.38 | 5.18 | 4.65 | 4.91 | 3.95 | 4.36 |
| WVTR | | | | | | | | | | | |
| Tanδ40 × | 19.55 | 23.64 | 17.47 | 21.67 | 25.42 | 14.34 | 14.59 | 8.62 | 21.80 | 9.65 | 11.29 |
| WVTR × DR | | | | | | | | | | | |
| 4 T − 3 S | −3.00 | 23.10 | 23.00 | −76.50 | 18.10 | −49.70 | −64.90 | −47.20 | −47.20 | −46.50 | −47.20 |

TABLE 5

| | | Ex. 23 | Ex. 24 | Ex. 25 | Ex. 26 | Ex. 27 | Ex. 28 | Ex. 29 | Ex. 30 | Ex. 31 | Ex. 32 | Ex. 33 |
|---|---|---|---|---|---|---|---|---|---|---|---|---|
| (A) Polyimide precursor | A-1 | | 100 | 100 | 100 | 100 | 100 | | | 100 | 100 | 100 |
| (g) | A-2 | | | | | | | 100 | | | | |
| | A-3 | | | | | | | | 100 | | | |
| | A-4 | | | | | | | | | | | |
| | A-5 | | | | | | | | | | | |
| | A-6 | | | | | | | | | | | |
| | A-7 | | | | | | | | | | | |
| | A-8 | | | | | | | | | | | |
| | A-9 | | | | | | | | | | | |
| | A-10 | | | | | | | | | | | |
| | A-11 | | | | | | | | | | | |
| | A-12 | | | | | | | | | | | |
| | A-13 | | | | | | | | | | | |
| | A-14 | | | | | | | | | | | |
| | A-15 | | | | | | | | | | | |
| | A-16 | | | | | | | | | | | |
| | A-17 | | | | | | | | | | | |
| | A-18 | | | | | | | | | | | |
| | A-19 | 100 | | | | | | | | | | |
| | A-20 | | | | | | | | | | | |
| | A-21 | | | | | | | | | | | |
| | A-22 | | | | | | | | | | | |
| | A-23 | | | | | | | | | | | |
| | A-24 | | | | | | | | | | | |
| | A-25 | | | | | | | | | | | |
| (B) Photopolymerization | B-1 | | | | 5 | 5 | 5 | 5 | | 5 | 5 | |
| initiator (g) | B-2 | | 5 | | | | | | | | | |
| | B-3 | 5 | | 5 | | | | | 5 | | | 5 |
| (C) Solvent (g) | C-1 | 180 | 180 | 180 | 180 | 180 | 180 | 180 | 180 | 180 | 180 | 180 |
| | C-2 | 20 | 20 | 20 | 20 | 20 | 20 | 20 | 20 | 20 | 20 | 20 |
| (D) Adhesion aid (g) | D-1 | 2 | 2 | 2 | | | | | | 2 | 2 | |
| | D-2 | | | | 2 | | | | 2 | | | |
| | D-3 | | | | | 2 | | | | | | |
| | D-4 | | | | | | 2 | | | | | |
| | D-5 | | | | | | | 2 | | | | |
| | D-6 | | | | | | | | 2 | | | 2 |
| (E) Radically | E-1 | 10 | 10 | 10 | 10 | 10 | 10 | 10 | 10 | | | |
| polymerizable | E-2 | | | | | | | | | 10 | | |
| compound (g) | E-3 | | | | | | | | | | 10 | |
| (F) Thermal crosslinking | F-1 | | | | | | | | | | | |
| agent (g) | F-2 | | | | | | | | | | | 10 |
| (G) Filler (g) | G-1 | | | | | | | | | | | |

TABLE 6

| | Ex. 23 | Ex. 24 | Ex. 25 | Ex. 26 | Ex. 27 | Ex. 28 | Ex. 29 | Ex. 30 | Ex. 31 | Ex. 32 | Ex. 33 |
|---|---|---|---|---|---|---|---|---|---|---|---|
| Resolution | A | A | A | A | A | A | A | A | A | B | A |
| Developing | 20 | 25 | 25 | 25 | 25 | 25 | 20 | 22 | 15 | 17 | 45 |
| time (s) | | | | | | | | | | | |
| Chemical | B | A | A | A | A | A | A | A | A | A | A |
| resistance | | | | | | | | | | | |
| Dissolution | 4.07 | 2.44 | 2.37 | 2.59 | 2.37 | 2.52 | 2.22 | 1.11 | 2.52 | 2.96 | 1.48 |
| rate: DR | | | | | | | | | | | |
| (nm/min) | | | | | | | | | | | |
| Dk (10 GHz) | 2.9 | 2.9 | 2.9 | 2.9 | 2.9 | 2.9 | 2.9 | 2.9 | 2.9 | 3.0 | 2.9 |
| Df (10 GHz) | 0.0061 | 0.0060 | 0.0060 | 0.0060 | 0.0060 | 0.0060 | 0.0058 | 0.0056 | 0.0066 | 0.0065 | 0.0054 |
| Dk (40 GHz) | 2.9 | 2.9 | 2.9 | 2.9 | 2.9 | 2.9 | 2.9 | 2.9 | 2.9 | 3.0 | 2.9 |
| Df (40 GHz) | 0.0071 | 0.0070 | 0.0070 | 0.0070 | 0.0070 | 0.0070 | 0.0068 | 0.0065 | 0.0076 | 0.0075 | 0.0063 |
| Moisture | 670 | 669 | 669 | 669 | 669 | 669 | 667 | 650 | 681 | 707 | 552 |
| permeability: | | | | | | | | | | | |
| WVTR | | | | | | | | | | | |
| Tanδ40 × | 4.76 | 4.70 | 4.70 | 4.70 | 4.70 | 4.70 | 4.54 | 4.23 | 5.17 | 5.32 | 3.48 |
| WVTR | | | | | | | | | | | |
| Tanδ40 × | 19.38 | 11.49 | 11.14 | 12.19 | 11.14 | 11.84 | 10.08 | 4.69 | 13.02 | 15.75 | 5.15 |
| WVTR × DR | | | | | | | | | | | |
| 4 T − 3 S | −47.20 | −47.20 | −47.20 | −47.20 | −47.20 | −47.20 | −47.20 | −47.20 | −47.20 | −47.20 | −47.20 |

TABLE 7

| | | | | | | | | Comp. | Comp. | Comp. | Comp. | Comp. | Comp. |
|---|---|---|---|---|---|---|---|---|---|---|---|---|---|
| | | Ex. 34 | Ex. 35 | Ex. 36 | Ex. 37 | Ex. 38 | Ex. 39 | Ex. 1 | Ex. 2 | Ex. 3 | Ex. 4 | Ex. 5 | Ex. 6 |
| (A) | A-1 | | | | 100 | 100 | 100 | | | | | | |
| Polyimide | A-2 | 100 | | | | | | | | | | | |
| precursor (g) | A-3 | | 100 | | | | | | | | | | |
| | A-4 | | | | | | | | | | | | |
| | A-5 | | | 100 | | | | | | | | | |
| | A-6 | | | | | | | | | | | | |
| | A-7 | | | | | | | | | | | | |
| | A-8 | | | | | | | | | | | | |
| | A-9 | | | | | | | | | | | | |
| | A-10 | | | | | | | | | | | | |
| | A-11 | | | | | | | | | | | | |
| | A-12 | | | | | | | | | | | | |
| | A-13 | | | | | | | | | | | | |
| | A-14 | | | | | | | | | | | | |
| | A-15 | | | | | | | | | | | | |
| | A-16 | | | | | | | | | | | | |
| | A-17 | | | | | | | | | | | | |
| | A-18 | | | | | | | | | | | | |
| | A-19 | | | | | | | | | | | | |
| | A-20 | | | | | | | 100 | | | | | |
| | A-21 | | | | | | | | 100 | | | | |
| | A-22 | | | | | | | | | 100 | | | |
| | A-23 | | | | | | | | | | 100 | | |
| | A-24 | | | | | | | | | | | 100 | |
| | A-25 | | | | | | | | | | | | 100 |
| (B) | B-1 | | | | 5 | 5 | 5 | 5 | 5 | 5 | 5 | 5 | 5 |
| Photopolymerization | B-2 | | | | | | | | | | | | |
| initiator (g) | B-3 | 5 | 5 | 5 | | | | | | | | | |
| (C) Solvent | C-1 | 180 | 180 | 180 | 180 | 180 | 180 | 180 | 180 | 180 | 180 | 180 | 180 |
| (g) | C-2 | 20 | 20 | 20 | 20 | 20 | 20 | 20 | 20 | 20 | 20 | 20 | 20 |
| (D) Adhesion | D-1 | | | 2 | 2 | 2 | 2 | 2 | 2 | 2 | 2 | 2 | 2 |
| aid (g) | D-2 | | | | | | | | | | | | |
| | D-3 | | | | | | | | | | | | |
| | D-4 | | | | | | | | | | | | |
| | D-5 | | | 2 | | | | | | | | | |
| | D-6 | 2 | 2 | | | | | | | | | | |
| (E) Radically | E-1 | | | | 10 | 10 | 10 | 10 | 10 | 10 | 10 | 10 | 10 |
| polymerizable | E-2 | | | | | | | | | | | | |
| compound | E-3 | | | | | | | | | | | | |
| (g) | | | | | | | | | | | | | |
| (F) Thermal | F-1 | | | 10 | 10 | | | | | | | | |
| crosslinking | F-2 | 10 | 10 | | | 10 | | | | | | | |
| agent (g) | | | | | | | | | | | | | |
| (G) Filler (g) | G-1 | | | 5 | | | 5 | | | | | | |

TABLE 8

| | Ex. 34 | Ex. 35 | Ex. 36 | Ex. 37 | Ex. 38 | Ex. 39 |
|---|---|---|---|---|---|---|
| Resolution | A | A | C | B | A | C |
| Developing | 28 | 36 | 22 | 13 | 13 | 14 |
| time (s) | | | | | | |
| Chemical | A | A | A | A | A | A |
| resistance | | | | | | |
| Dissolution | 1.85 | 1.78 | 2.52 | 1.85 | 1.70 | 2.59 |
| rate: DR | | | | | | |
| (nm/min) | | | | | | |
| Dk (10 GHz) | 2.9 | 2.9 | 2.9 | 3.3 | 3.1 | 3.0 |
| Df (10 GHz) | 0.0056 | 0.0049 | 0.0058 | 0.0060 | 0.0053 | 0.0057 |
| Dk (40 GHz) | 2.9 | 2.9 | 2.9 | 3.3 | 3.1 | 3.0 |
| Df (40 GHz) | 0.0065 | 0.0060 | 0.007 | 0.0070 | 0.0063 | 0.0067 |
| Moisture | 552 | 535 | 520 | 736 | 635 | 669 |
| permeability: | | | | | | |
| WVTR | | | | | | |
| Tanδ40 × | 3.59 | 3.21 | 3.66 | 5.17 | 4.02 | 4.47 |
| WVTR | | | | | | |
| Tanδ40 × | 6.64 | 5.71 | 9.17 | 9.58 | 6.85 | 11.58 |
| WVTR × DR | | | | | | |
| 4 T − 3 S | −47.20 | −47.20 | −46.50 | −47.20 | −47.20 | −47.20 |
| | Comp. | Comp. | Comp. | Comp. | Comp. | Comp. |
| | Ex. 1 | Ex. 2 | Ex. 3 | Ex. 4 | Ex. 5 | Ex. 6 |
| Resolution | D | C | D | A | A | B |
| Developing | 60 | 60 | 45 | 80 | 80 | 80 |
| time (s) | | | | | | |
| Chemical | A | A | C | A | A | A |
| resistance | | | | | | |
| Dissolution | 2.00 | 1.63 | 5.04 | 2.59 | 2.41 | 2.59 |
| rate: DR | | | | | | |
| (nm/min) | | | | | | |
| Dk (10 GHz) | 3.2 | 3.2 | 3.0 | 3.1 | 3.1 | 3.1 |
| Df (10 GHz) | 0.018 | 0.0191 | 0.0120 | 0.0140 | 0.0149 | 0.0143 |
| Dk (40 GHz) | 3.1 | 3.1 | 3.0 | 3.0 | 3.0 | 3.0 |
| Df (40 GHz) | 0.021 | 0.022 | 0.0140 | 0.0160 | 0.0168 | 0.0163 |
| Moisture | 876 | 832 | 850 | 752 | 717 | 702 |
| permeability: | | | | | | |
| WVTR | | | | | | |
| Tanδ40 × | 18.40 | 18.35 | 11.90 | 12.03 | 12.05 | 11.44 |
| WVTR | | | | | | |
| Tanδ40 × | 36.79 | 29.90 | 59.94 | 31.19 | 29.00 | 29.67 |
| WVTR × DR | | | | | | |
| 4 T − 3 S | −106.20 | −106.20 | −86.40 | −79.90 | −79.90 | −79.90 |

TABLE 9

| | | | | Aliphatic | Photosensitive | | |
|---|---|---|---|---|---|---|---|
| (A) | | | | hydrocarbon group | group | End- | |
| Polyimide | | Terminal | | concentration | concentration | capping | A: |
| precursor | A/B | monomer | Mw | T (wt %) | S (wt %) | value | Acid |
| A-1 | 9/8 | Acid | 22,000 | 8.6 | 27.2 | 0.04 | BPADA |
| A-2 | 9/8 | Acid | 15,000 | 8.6 | 27.2 | 0.02 | BPADA |
| A-3 | 11/12 | Amine | 17,000 | 8.6 | 27.2 | 0.09 | BPADA |
| A-4 | 9/8 | Acid | 21,000 | 4.4 | 27.5 | 0.07 | ODPA |
| A-5 | 9/8 | Acid | 20,000 | 8.4 | 26.7 | 0.07 | ODPA |
| A-6 | 9/8 | Acid | 20,000 | 8.6 | 27.2 | 0.06 | BPDA |
| A-7 | 9/8 | Acid | 23,000 | 9.8 | 22 | 0.04 | BPADA |
| A-8 | 9/8 | Acid | 21,000 | 16.2 | 22.6 | 0.06 | BPDA |
| A-9 | 9/8 | Acid | 19,000 | 20.7 | 19.9 | 0.04 | BPADA |
| A-10 | 9/8 | Acid | 13,000 | 25.1 | 25.8 | 0.1 | PD |
| A-11 | 9/8 | Acid | 19,000 | 4.2 | 31.1 | 0.07 | ODPA |
| A-12 | 9/8 | Acid | 15,000 | 22.3 | 23.7 | 0.07 | ODPA |
| A-13 | 9/8 | Acid | 18,000 | 9.7 | 29.5 | 0.1 | PD |
| A-14 | 9/8 | Acid | 23,000 | 8.6 | 31.2 | 0.04 | BPADA |
| A-15 | 9/8 | Acid | 18,000 | 8.6 | 27.2 | 0.04 | BPADA |
| A-16 | 15/14 | Acid | 16,000 | 8.6 | 27.2 | 0.08 | BPADA |
| A-17 | 14/15 | Amine | 21,000 | 8.4 | 27.5 | 0.07 | ODPA |
| A-18 | 14/15 | Amine | 17,000 | 8.6 | 27.2 | 0.06 | BPADA |
| A-19 | 15/14 | Acid | 16,000 | 8.6 | 27.2 | 0.08 | BPADA |
| A-20 | 7/6 | Acid | 22,000 | 0.0 | 35.4 | — | ODPA |
| A-21 | 5/6 | Amine | 20,000 | 0.0 | 35.4 | 0.05 | ODPA |
| A-22 | 7/6 | Acid | 23,000 | 0.0 | 28.8 | — | ODPA |
| A-23 | 7/6 | Acid | 19,000 | 6.2 | 34.9 | — | ODPA |
| A-24 | 5/6 | Amine | 21,000 | 6.2 | 34.9 | 0.05 | ODPA |
| A-25 | 7/6 | Acid | 20,000 | 6.2 | 34.9 | 0.01 | ODPA |

| | | Photo- | Terminal | | Terminal | |
|---|---|---|---|---|---|---|
| (A) | | sensitive | modifier | End- | photo- | |
| Polyimide | B: | group (first | (second | capping | sensitive | Terminal |
| precursor | Amine | compound) | compound) | method | group | structure |
| A-1 | m-TB | HEMA | 2-Isocyanatoethyl | Pre- | Methacrylic | Ends |
| | | | methacrylate | capping | group | (1), (2) |
| A-2 | m-TB | HEMA | 2-Isocyanatoethyl | Pre- | Methacrylic | End |
| | | | methacrylate | capping | group | (3) |
| A-3 | m-TB | HEMA | 2-Isocyanatoethyl | Pre- | Methacrylic | Urea |
| | | | methacrylate | capping | group | bond |
| A-4 | BAPP | HEMA | 2-Isocyanatoethyl | Pre- | Methacrylic | Ends |
| | | | methacrylate | capping | group | (1), (2) |
| A-5 | MBAPP | HEMA | 2-Isocyanatoethyl | Pre- | Methacrylic | Ends |
| | | | methacrylate | capping | group | (1), (2) |
| A-6 | MBAPP | HEMA | 2-Isocyanatoethyl | Pre- | Methacrylic | Ends |
| | | | methacrylate | capping | group | (1), (2) |
| A-7 | MBAPP | HEMA | 2-Isocyanatoethyl | Pre- | Methacrylic | Ends |
| | | | methacrylate | capping | group | (1), (2) |
| A-8 | DTBAB | HEMA | 2-Isocyanatoethyl | Pre- | Methacrylic | Ends |
| | | | methacrylate | capping | group | (1), (2) |
| A-9 | X-1 | HEMA | 2-Isocyanatoethyl | Pre- | Methacrylic | Ends |
| | | | methacrylate | capping | group | (1), (2) |
| A-10 | X-1 | HEMA | 2-Isocyanatoethyl | Pre- | Methacrylic | Ends |
| | | | methacrylate | capping | group | (1), (2) |
| A-11 | MBAPP | HEMA | 2-Isocyanatoethyl | Pre- | Methacrylic | Ends |
| | DADPE | | methacrylate | capping | group | (1), (2) |
| A-12 | X-1 | HEMA | 2-Isocyanatoethyl | Pre- | Methacrylic | Ends |
| | | | methacrylate | capping | group | (1), (2) |
| A-13 | MBAPP | HEMA | 2-Isocyanatoethyl | Pre- | Methacrylic | Ends |
| | | | methacrylate | capping | group | (1), (2) |
| A-14 | m-TB | HBMA | 2-Isocyanatoethyl | Pre- | Methacrylic | Ends |
| | | | methacrylate | capping | group | (1), (2) |
| A-15 | m-TB | HEMA | 2-Isocyanatoethyl | Pre- | Methacrylic | Ends |
| | | | methacrylate 1,1- | capping | group | (1), (2) |
| | | | (bisacryloyloxymeth- | | | |
| | | | yl)ethyl | | | |
| | | | isocyanate | | | |
| A-16 | m-TB | HEMA | Allylamine | Pre- | Allyl group | Imide |
| | | | | capping | | bond |
| A-17 | MBAPP | HEMA | 2-Isocyanatoethyl | Pre- | Methacrylic | Urea |
| | | | methacrylate 1,1- | capping | group | bond |
| | | | (bisacryloyloxymeth- | | | |
| | | | yl)ethyl | | | |
| | | | isocyanate | | | |
| A-18 | m-TB | HEMA | Methacrylic acid | Pre- | Methacrylic | Amide |
| | | | chloride | capping | group | bond |
| A-19 | m-TB | HEMA | 5-Norbornene-2- | Pre- | Cycloalkenyl | Imide |
| | | | methylamine | capping | group | bond |
| A-20 | DADPE | HEMA | — | — | | None |
| A-21 | DADPE | HEMA | 2-Isocyanatoethyl | Post- | Methacrylic | Urea |
| | | | methacrylate | capping | group | bond |
| A-22 | BAPB | HEMA | — | — | | None |
| A-23 | m-TB | HEMA | — | — | | None |
| A-24 | m-TB | HEMA | 2-Isocyanatoethyl | Post- | Methacrylic | Urea |
| | | | methacrylate | capping | group | bond |
| A-25 | m-TB | HEMA | 4-Vinylaniline | Post- | Stynyl group | Amide |
| | | | | capping | | bond |

As is apparent from Tables 1 to 9, in Examples, by introducing a terminal structure in advance into the monomer before polymerization (pre-capping), it was possible to produce a cured resin film which has satisfactory resolution and chemical resistance, and also has low dielectric properties. To the contrary, sufficient results could not be obtained in Comparative Examples. In the parameters consisting of the moisture permeability and dielectric loss tangent, Examples showed lower values than those of Comparative Examples, which suggested less frequency dependence of the dielectric loss tangent, in addition to the above properties.

### INDUSTRIAL APPLICABILITY

By using the photosensitive resin composition of the present disclosure, it is possible to produce a cured resin film having excellent relief pattern resolution, low dielectric properties, low moisture permeability and satisfactory chemical resistance, which can be suitably used in the field of photosensitive materials useful in the production of electrical and electronic materials such as semiconductor devices and multilayer wiring boards.

### REFERENCE SIGNS LIST

1: Proton peak of polymerizable functional group derived from end
2: Proton peak of polymerizable functional group derived from repeating unit

1. A photosensitive resin composition comprising:
(A) 100 parts by mass of a polyimide precursor resin;
(B) 0.5 to 10 parts by mass of a photopolymerization initiator; and
(C) 50 to 500 parts by mass of a solvent;
wherein the polyimide precursor resin (A) comprises at least one terminal structure selected from the group consisting of the following general formulas (1) to (3): 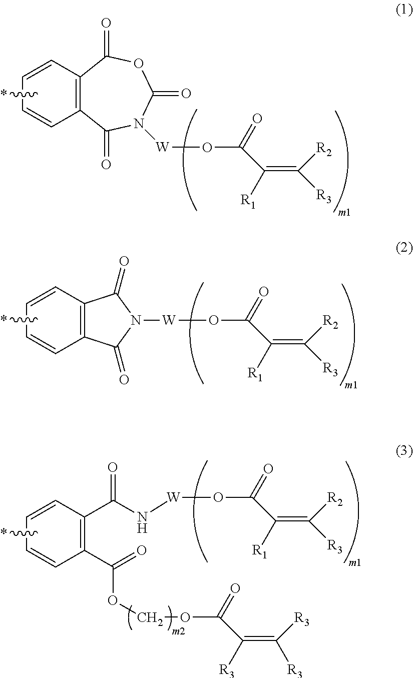
wherein W is a divalent to trivalent organic group, R₁ to R₃ are each independently a hydrogen atom or a monovalent organic group having 1 to 3 carbon atoms, mi is a group represented by an integer of 1 to 2, m² is a group represented by an integer of 2 to 10, and * means bonding to the main chain of the resin, and
wherein, in polyimide of a polyimide cured film obtained by heating and curing the photosensitive resin composition at 350° C., aliphatic hydrocarbon group concentration T, which is the ratio of the total molecular weight of aliphatic hydrocarbon groups to the molecular weight of repeating units including structures derived from tetracarboxylic dianhydride and a diamine compound, is 4 wt % to 35 wt %; or
a photosensitive resin composition comprising:
(A) 100 parts by mass of a polyimide precursor resin;
(B) 0.5 to 10 parts by mass of a photosensitive agent and
(C) 100 to 300 parts by mass of a solvent;
wherein, in polyimide of a polyimide cured film obtained by heating and curing the photosensitive resin composition at 350° C., aliphatic hydrocarbon group concentration T which is the ratio of the total molecular weight of aliphatic hydrocarbon groups to the molecular weight of repeating units including structures derived from tetracarboxylic dianhydride and a diamine compound, and photosensitive group concentration S which is the ratio of the total molecular weight of photosensitive groups to the molecular weight of repeating units in the polyimide precursor resin (A) satisfy the following formula (1):
−77≤4T−3S≤44 (1)
and wherein the polyimide precursor resin (A) has the other reactive unsaturated bonds which are polymerized by heat or light at the resin end, and are different from the reactive unsaturated bond side chain included in the repeating units.

2. (canceled)

3. The photosensitive resin composition according to claim 1, wherein the polyimide precursor resin (A) is represented by the following general formula (4): 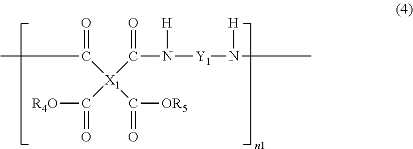
wherein X₁ is a tetravalent organic group having 6 to 40 carbon atoms, Y₁ is a divalent organic group having 6 to 40 carbon atoms, n₁ is an integer of 2 to 150, and R₄ and R₅ are each independently a hydrogen atom or a monovalent organic group having 1 to 40 carbon atoms, in which at least one of R₄ and R₅ is a group represented by the following general formula (5): 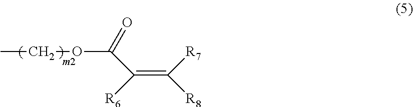
wherein R₆, R₇ and R₈ are each independently a hydrogen atom or a monovalent organic group having 1 to 3 carbon atoms, and m₂ is an integer of 2 to 10.

4. The photosensitive resin composition according to claim 1, wherein photosensitive group concentration S, which is the ratio of the total molecular weight of photosensitive groups to the molecular weight of repeating units in the polyimide precursor resin (A) represented by the general formula (4), is 15 wt % to 35 wt %.

5. The photosensitive resin composition according to claim 1, wherein the polyimide precursor resin (A) includes a structure represented by the following general formula (6): 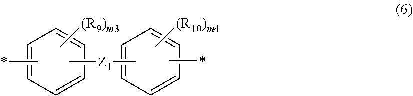
wherein R₉ and R₁₀ are each independently an organic group having 1 to 10 carbon atoms, m₃ and m₄ are an integer selected from 1 to 4, Z is selected from the group consisting of a single bond, an organic group having 1 to 30 carbon atoms and an organic group containing a heteroatom, and * means bonding to the main chain of the resin.

6. The photosensitive resin composition according to claim 1, further comprising (D) a silane coupling agent.

7. The photosensitive resin composition according to claim 1, further comprising (E) a radically polymerizable compound.

8. The photosensitive resin composition according to claim 1, further comprising (F) a thermal crosslinking agent.

9. The photosensitive resin composition according to claim 1, further comprising (G) a filler.

10. The photosensitive resin composition according to claim 1, wherein the polyimide precursor resin (A) includes a terminal structure derived from tetracarboxylic dianhydride at the end of the main chain, and
wherein, in ¹H-NMR, when a peak area of an amide group derived from the main chain structure is 1.0, an end-capping value, which indicates an end-capping ratio, is 0.02 or more.

11. A photosensitive resin composition comprising:
(A) 100 parts by mass of a polyimide precursor resin;
(B) 0.5 to 10 parts by mass of a photopolymerization initiator; and
(C) 50 to 500 parts by mass of a solvent;
wherein the polyimide precursor resin (A) includes a terminal structure derived from tetracarboxylic dianhydride or diamine at the end of the main chain, and
wherein, in ¹H-NMR, when a peak area of an amide group derived from the main chain structure is 1.0, an end-capping value, which indicates an end-capping ratio, is 0.02 or more when the terminal structure is derived from tetracarboxylic dianhydride, or 0.06 or more when the terminal structure is derived from diamine.

12. (canceled)

13. A method for producing a polyimide cured film, the method comprising the following:
a step of applying the photosensitive resin composition according to claim 1 on a substrate to form a photosensitive resin layer on the substrate;
heating and drying the obtained photosensitive resin layer;
exposing the heat-dried photosensitive resin layer;
developing the exposed photosensitive resin layer; and
heat-treating the developed photosensitive resin layer to form a polyimide cured film.

14. A method for producing a polyimide cured film, which comprises applying the resin composition according to claim 1 on a substrate, and subjecting the substrate to an exposure treatment, a development treatment and then a heat treatment, wherein the cured film is an insulating film used for rewiring applications, and the cured film has a dielectric loss tangent within a range of 3.0×10⁻³ to 1.3×10⁻² as measured at 40 GHz by the perturbation type split cylinder resonator method.

15. A polyimide cured film which has a dielectric loss tangent of 3.0×10⁻³ to 1.3×10⁻² as measured at a frequency of 40 GHz by the perturbation type split cylinder resonator method, and satisfies the following formula (2):
3.0<tan δ₄₀×WVTR<10.0 (2)
wherein tan δ₄₀ represents the dielectric loss tangent as measured at a frequency of 40 GHz by the perturbation type split cylinder resonator method, and WVTR represents the moisture permeability of a 10 μm thick polyimide cured film.

16. The polyimide cured film according to claim 15, wherein the dielectric loss tangent as measured at a frequency of 40 GHz by the perturbation type split cylinder resonator method is 3.0×10⁻³ to 1.3×10⁻² and satisfies the following formula (3):
4.0<tan δ₄₀×WVTR×DR<29.0 (3)
wherein tan δ₄₀ represents the dielectric loss tangent as measured at a frequency of 40 GHz by the perturbation type split cylinder resonator method, WVTR represents the moisture permeability of a polyimide cured film in terms of a thickness of 10 μm, and DR represents a dissolution rate in a chemical resistance test.

17. A method for producing a photosensitive resin composition, the photosensitive resin composition comprising:
(A) 100 parts by mass of a polyimide precursor resin;
(B) 0.5 to 10 parts by mass of a photopolymerization initiator; and
(C) 50 to 500 parts by mass of a solvent;
wherein the method comprises synthesizing the polyimide precursor resin (A) and mixing the polyimide precursor resin (A), the photopolymerization initiator (B) and the solvent (C) to obtain a photosensitive resin composition, wherein
the synthesizing comprises the following:
monomer preparation by obtaining an acid component monomer and/or a diamine monomer having a second compound introducing portion by (i) and/or (ii):
(i) reacting tetracarboxylic dianhydride with a first compound having a reactive substituent which reacts with heat or light to generate a first compound introducing portion and carboxyl groups, reacting with a second compound having a reactive substituent that reacts with heat or light, which is different from the first compound, or reacting tetracarboxylic dianhydride with a second compound having a reactive substituent which reacts with heat or light to generate a second compound introducing portion and carboxyl groups, and then reacting with a first compound having a reactive substituent which reacts with heat or light, which is different from the second compound, to obtain an acid component monomer having a second compound introducing portion, and/or
(ii) reacting a diamine compound with a second compound having a reactive substituent which reacts with heat or light to obtain a diamine monomer having a second compound introducing portion; and
polymerization by synthesizing a polyimide precursor by subjecting an acid component monomer and/or a diamine monomer having a second compound introducing portion, tetracarboxylic dianhydride and a diamine compound to a condensation reaction, and
wherein the polyimide precursor resin (A) has a reactive substituent derived from the second compound at the main chain end; or
a method for producing a polyimide precursor resin, the method comprising the following:
monomer preparation by obtaining an acid component monomer and/or a diamine monomer having a second compound introducing portion by (i) and/or (ii):
(i) reacting tetracarboxylic dianhydride with a first compound having a reactive substituent which reacts with heat or light to generate a first compound introducing portion and carboxyl groups, reacting with a second compound having a reactive substituent which reacts with heat or light, which is different from the first compound, or reacting tetracarboxylic dianhydride with a second compound having a reactive substituent which reacts with heat or light to generate a second compound introducing portion and carboxyl groups, and then reacting with a first compound having a reactive substituent which reacts with heat or light, which is different from the second compound, to obtain an acid component monomer having a second compound introducing portion, and/or
(ii) reacting a diamine compound with a second compound having a reactive substituent which reacts with heat or light to obtain a diamine monomer having a second compound introducing portion; and
polymerization by synthesizing a polyimide precursor by subjecting an acid component monomer and/or a diamine monomer having a second compound introducing portion, tetracarboxylic dianhydride and a diamine compound to a condensation reaction, and
wherein the polyimide precursor resin has a reactive substituent derived from the second compound at the main chain end.

18. (canceled)
